(19) United States
(12) Patent Application Publication
(10) Pub. No.: US 2025/0079306 A1
(43) Pub. Date: Mar. 6, 2025

(54) SEMICONDUCTOR MEMORY DEVICE

(71) Applicant: Kioxia Corporation, Tokyo (JP)

(72) Inventor: Megumi ISHIDUKI, Yokkaichi (JP)

(73) Assignee: Kioxia Corporation, Tokyo (JP)

(21) Appl. No.: 18/755,786

(22) Filed: Jun. 27, 2024

(30) Foreign Application Priority Data
Sep. 1, 2023 (JP) 2023-142611

(51) Int. Cl. H01L 23/528; G11C 16/04; H01L 23/522; H01L 23/532; H10B 43/10; H10B 43/27

(52) U.S. Cl. CPC H01L 23/5283; G11C 16/0483; H01L 23/5226; H01L 23/53295; H10B 43/10; H10B 43/27

(57) ABSTRACT

A semiconductor memory device includes conductive layers stacked in a stacking direction, a semiconductor column opposed to the conductive layers, a semiconductor member connected to the semiconductor column, a contact electrode connected to the semiconductor member, a first insulating member separating a part of the conductive layers in a first direction, and a second insulating member disposed inside the first insulating member. The contact electrode includes a first conductive region provided at an opposite side of the semiconductor column in the stacking direction with respect to a surface of the semiconductor member at the contact electrode side in the stacking direction and a second conductive region provided at a semiconductor column side in the stacking direction with respect to the surface of the semiconductor member between the semiconductor member and the second insulating member. The second conductive region is in contact with the second insulating member.

### CROSS-REFERENCE TO RELATED APPLICATIONS

This application is based upon and claims the benefit of Japanese Patent Application No. 2023-142611, filed on Sep. 1, 2023, the entire contents of which are incorporated herein by reference.

### BACKGROUND

### Field

Embodiments described herein relate generally to a semiconductor memory device.

### Description of the Related Art

There has been known a semiconductor memory device including a plurality of conductive layers stacked in a stacking direction, a semiconductor column that extends in the stacking direction and is opposed to the plurality of conductive layers, and a gate insulating film disposed between the plurality of conductive layers and the semiconductor column. The gate insulating film includes, for example, one of an insulating electric charge accumulating film of silicon nitride (SiN) or the like, and an electrically conductive electric charge accumulating film, such as a floating gate.

### BRIEF DESCRIPTION OF THE DRAWINGS

FIG. 1 is a schematic circuit diagram illustrating a configuration of a semiconductor memory device according to a first embodiment;

FIG. 2 is a schematic plan view illustrating a part of the configuration of the semiconductor memory device;

FIG. 3 is a schematic plan view illustrating a part of the configuration of the semiconductor memory device;

FIG. 4 is a schematic cross-sectional view illustrating a part of the configuration of the semiconductor memory device;

FIG. 5 is a schematic cross-sectional view illustrating a part of the configuration of the semiconductor memory device;

FIG. 6 is a schematic cross-sectional view illustrating a part of the configuration of the semiconductor memory device;

FIG. 7 is a schematic cross-sectional view illustrating a part of the configuration of the semiconductor memory device;

FIG. 8 is a schematic XY cross-sectional view illustrating a part of the configuration of the semiconductor memory device;

FIG. 9 is a schematic cross-sectional view for describing a method for manufacturing the semiconductor memory device according to the first embodiment;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing the manufacturing method;

FIG. 29 is a schematic cross-sectional view for describing the manufacturing method;

FIG. 30 is a schematic cross-sectional view for describing the manufacturing method;

FIG. 31 is a schematic cross-sectional view illustrating a part of a configuration of a semiconductor memory device according to a second embodiment;

FIG. 32 is a schematic XY cross-sectional view illustrating a part of the configuration of the semiconductor memory device;

FIG. 33 is a schematic cross-sectional view for describing a method for manufacturing the semiconductor memory device according to the second embodiment;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view illustrating a part of a configuration of a semiconductor memory device according to a third embodiment;

FIG. 38 is a schematic cross-sectional view illustrating a part of a configuration of a semiconductor memory device according to a fourth embodiment;

FIG. 39 is a schematic XY cross-sectional view illustrating a part of the configuration of the semiconductor memory device;

FIG. 40 is a schematic cross-sectional view for describing a method for manufacturing the semiconductor memory device according to the fourth embodiment;

FIG. 41 is a schematic cross-sectional view for describing the manufacturing method;

FIG. 42 is a schematic cross-sectional view illustrating a part of a configuration of a semiconductor memory device according to a fifth embodiment;

FIG. 43 is a schematic XY cross-sectional view illustrating a part of the configuration of the semiconductor memory device;

FIG. 44 is a schematic cross-sectional view illustrating a part of a configuration of a semiconductor memory device according to a sixth embodiment;

FIG. 45 is a schematic cross-sectional view illustrating a part of a configuration of a semiconductor memory device according to a seventh embodiment;

FIG. 46 is a schematic XY cross-sectional view illustrating a part of the configuration of the semiconductor memory device;

FIG. 47 is a schematic cross-sectional view for describing a method for manufacturing the semiconductor memory device according to the seventh embodiment;

FIG. 48 is a schematic cross-sectional view for describing the manufacturing method;

FIG. 49 is a schematic cross-sectional view for describing the manufacturing method;

FIG. 50 is a schematic cross-sectional view for describing the manufacturing method;

FIG. 51 is a schematic XY cross-sectional view illustrating a part of a configuration of a semiconductor memory device according to another embodiment; and

FIG. 52 is a schematic XY cross-sectional view illustrating a part of a configuration of a semiconductor memory device according to another embodiment.

### DETAILED DESCRIPTION

A semiconductor memory device according to one embodiment comprises: a plurality of conductive layers stacked in a stacking direction; a first semiconductor column extending in the stacking direction and opposed to the plurality of conductive layers; a first gate insulating film disposed between the plurality of conductive layers and the first semiconductor column and including a first electric charge accumulating film; a first semiconductor member connected to one end in the stacking direction of the first semiconductor column; a first contact electrode extending in the stacking direction and connected to the first semiconductor member; a first insulating member disposed at a position overlapping with a part of the first semiconductor column and a part of the first gate insulating film when viewed in the stacking direction, the first insulating member separating a part of the conductive layers arranged at a first contact electrode side in the stacking direction among the plurality of conductive layers in a first direction intersecting with the stacking direction; and a second insulating member disposed at least at a first position in the stacking direction corresponding to the first semiconductor member inside the first insulating member. The first contact electrode includes a first conductive region and a second conductive region. The first conductive region is provided at an opposite side of the first semiconductor column in the stacking direction with respect to a surface of the first semiconductor member at the first contact electrode side in the stacking direction. The second conductive region is provided at a first semiconductor column side in the stacking direction with respect to the surface of the first semiconductor member between the first semiconductor member and the second insulating member. The second conductive region is in contact with the second insulating member.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, a direction intersecting with a surface of the substrate is referred to as a stacking direction in some cases. A direction along a predetermined plane intersecting with the stacking direction may be referred to as a first direction, and a direction along the plane and intersecting with the first direction may be referred to as a second direction. The stacking direction may correspond to the Z-direction and need not correspond to the Z-direction. The first direction and the second direction may and need not each correspond to any of the X-direction or the Y-direction.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

### First Embodiment

### [Circuit Configuration]

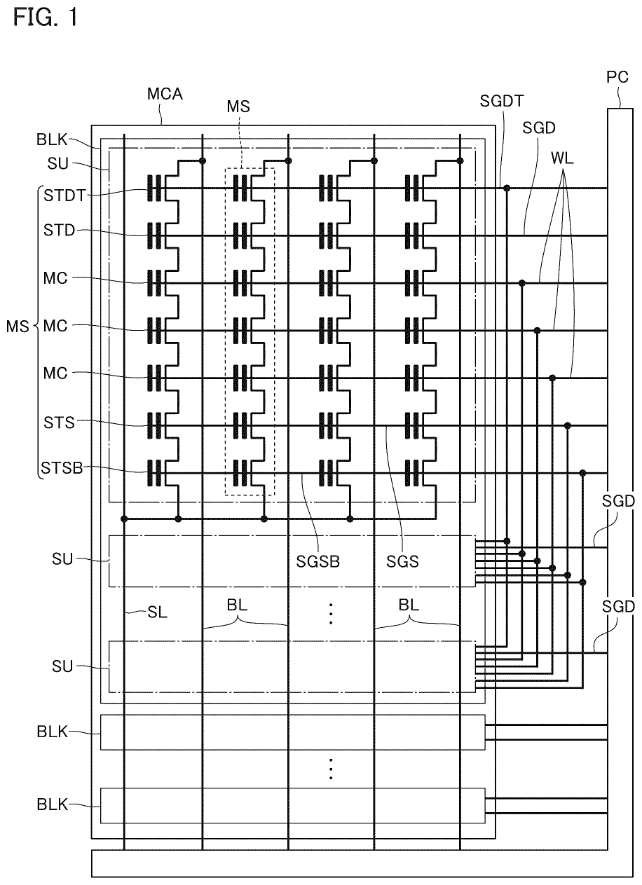

FIG. 1 is a schematic circuit diagram illustrating a configuration of a semiconductor memory device according to the first embodiment. As illustrated in FIG. 1, the semiconductor memory device according to the embodiment includes a memory cell array MCA and a peripheral circuit PC.

The memory cell array MCA includes a plurality of memory blocks BLK. These plurality of memory blocks BLK each include a plurality of string units SU. These plurality of string units SU each include a plurality of memory strings MS. These plurality of memory strings MS have one ends each connected to the peripheral circuit PC via a bit line BL. These plurality of memory strings MS have the other ends each connected to the peripheral circuit PC via a common source line SL.

The memory string MS includes drain-side select transistors STDT, STD, a plurality of memory cells MC (memory transistors), and source-side select transistors STS, STSB. The drain-side select transistors STDT, STD, the plurality of memory cells MC, and the source-side select transistors STS, STSB are connected in series between the bit line BL and the source line SL. Hereinafter, the drain-side select transistors STDT, STD and the source-side select transistors STS, STSB may be simply referred to as select transistors (STDT, STD, STS, STSB).

The memory cell MC is a field-effect type transistor. The memory cell MC includes a part of a semiconductor column, a gate insulating film, and a gate electrode. A part of the semiconductor column functions as a channel region. The gate insulating film includes an electric charge accumulating film. A threshold voltage of the memory cell MC varies corresponding to an electric charge amount in the electric charge accumulating film. The memory cell MC stores data of 1 bit or a plurality of bits. The gate electrodes of the plurality of memory cells MC corresponding to one memory string MS are connected to respective word lines WL. Each of these word lines WL is connected in common to all of the memory strings MS in one memory block BLK.

The select transistors (STDT, STD, STS, STSB) are field-effect type transistors. The select transistors (STDT, STD, STS, STSB) each include a part of the semiconductor column, a gate insulating film, and a gate electrode. A part of the semiconductor column functions as a channel region. The gate electrodes of the select transistors (STDT, STD, STS, STSB) are connected to select gate lines (SGDT, SGD, SGS, SGSB), respectively. One drain-side select gate line SGDT is connected in common to all of the memory strings MS in one memory block BLK. One drain-side select gate line SGD is connected in common to all of the memory strings MS in one string unit SU. One source-side select gate line SGS is connected in common to all of the memory strings MS in one memory block BLK. One source-side select gate line SGSB is connected in common to all of the memory strings MS in one memory block BLK.

The peripheral circuit PC includes, for example, a voltage generation circuit that generates an operating voltage, a voltage transfer circuit that transfers the generated operating voltage to selected bit line BL, word line WL, source line SL, select gate lines (SGDT, SGD, SGS, SGSB), and the like, a sense amplifier module connected to the bit lines BL, and a sequencer that controls them.

### [Structure]

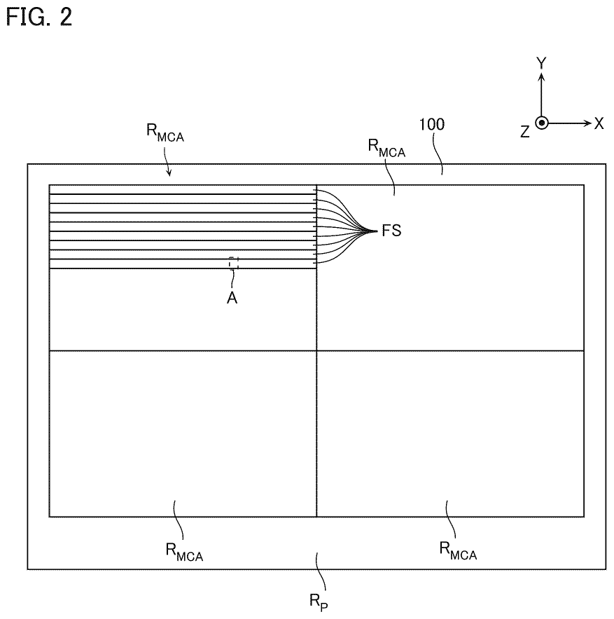

Next, with reference to FIG. 2 to FIG. 8, a structure of the semiconductor memory device according to the first embodiment is described.

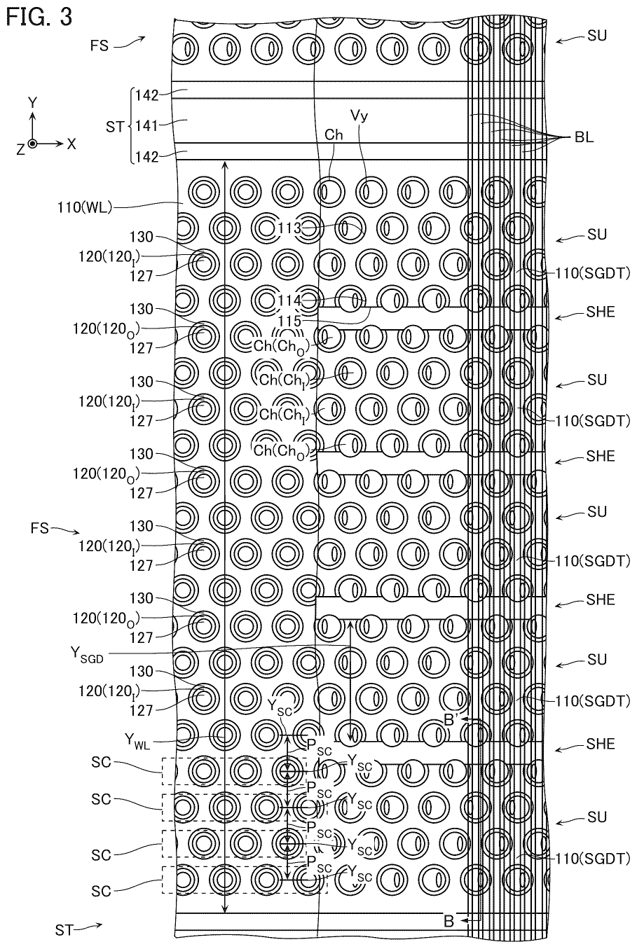

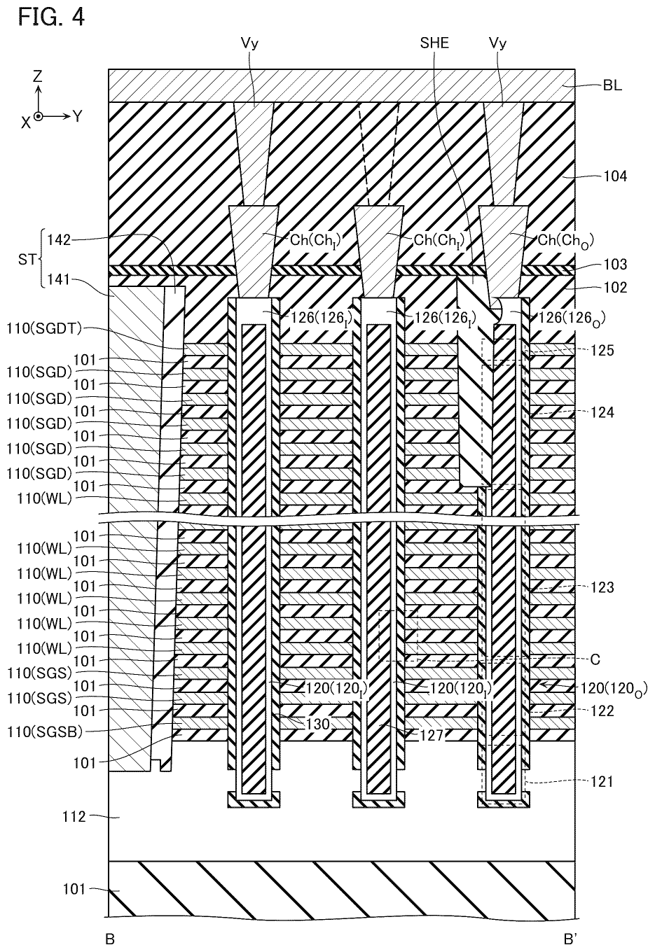

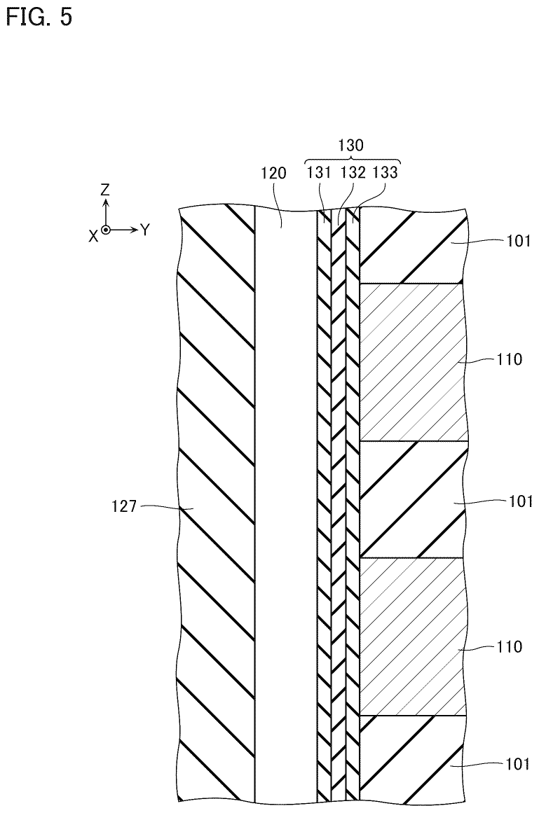

FIG. 2 is a schematic plan view illustrating a part of the configuration of the semiconductor memory device. FIG. 3 is a schematic plan view illustrating a part of the configuration of the semiconductor memory device, and illustrates an enlarged part indicated by A in FIG. 2. A part of FIG. 3 illustrates an XY cross-sectional surface at a height position corresponding to a conductive layer 110 (WL) described later. A part of FIG. 3 illustrates a plane in which the bit lines BL and insulating layers 102, 103, 104 described later are omitted. A part of FIG. 3 illustrates the bit lines BL. FIG. 4 is a schematic cross-sectional view illustrating a part of the configuration of the semiconductor memory device. FIG. 4 illustrates a cross-sectional surface of the structure illustrated in FIG. 3 taken along the line B-B′ and viewed in an arrow direction. FIG. 5 is a schematic cross-sectional view illustrating a part of the configuration of the semiconductor memory device, and illustrates an enlarged part indicated by C in FIG. 4. While FIG. 5 illustrates the YZ cross-sectional surface, when a cross-sectional surface taken along a center axis of a semiconductor column 120 other than the YZ cross-sectional surface (for example, an XZ cross-sectional surface) is observed, the structure similar to FIG. 5 is observed.

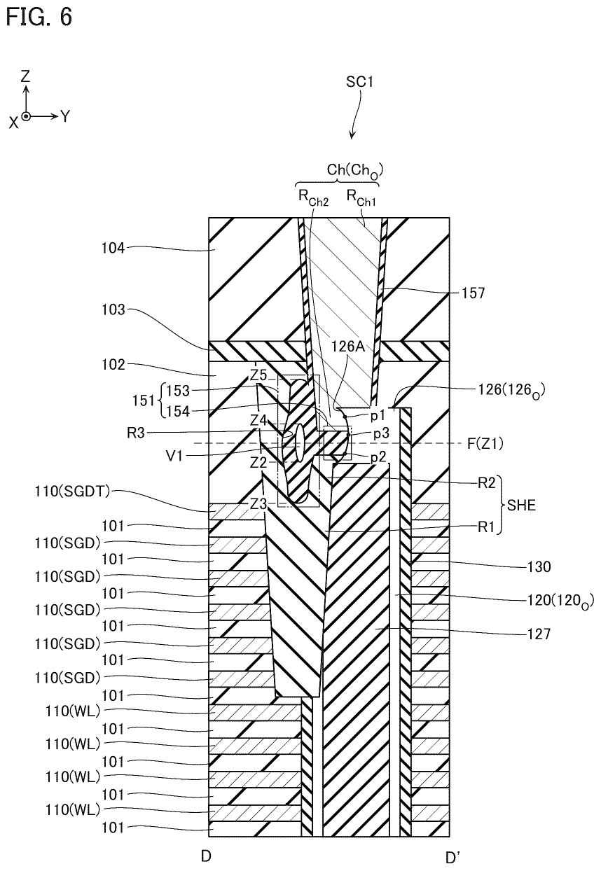

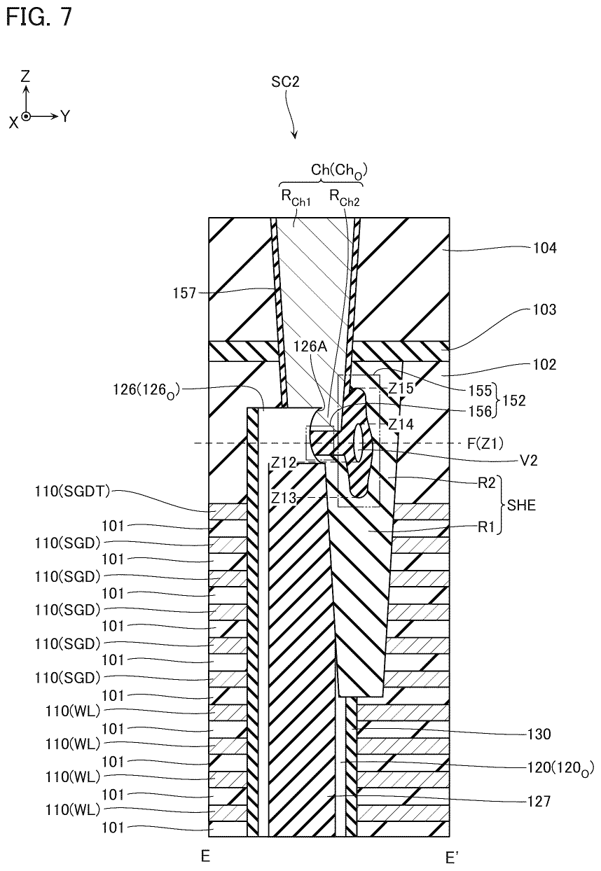

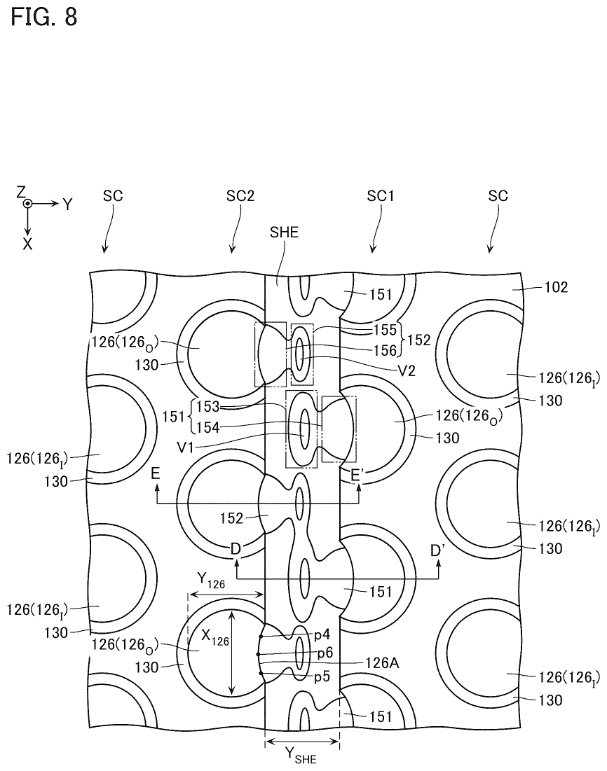

FIG. 6 and FIG. 7 are schematic cross-sectional views illustrating a part of the configuration of the semiconductor memory device. FIG. 8 is a schematic XY cross-sectional view illustrating a part of the configuration of the semiconductor memory device. FIG. 6 illustrates a cross-sectional surface corresponding to a part of FIG. 4. FIG. 6 illustrates a cross-sectional surface of the structure illustrated in FIG. 8 taken along the line D-D′ and viewed in an arrow direction. FIG. 7 illustrates a cross-sectional surface of the structure illustrated in FIG. 8 taken along the line E-E′ and viewed in an arrow direction. FIG. 8 illustrates an XY cross-sectional surface at a height position corresponding to a dashed line F illustrated in FIG. 6 and FIG. 7. The dashed line F indicates a height position Z1 corresponding to a semiconductor member 126 described later.

FIG. 2 to FIG. 8 are schematic views, and the configurations are partially omitted in some cases. For example, in FIG. 4, an insulating member 151 (FIG. 6, FIG. 8) described later is omitted.

The semiconductor memory device according to the first embodiment includes, for example, as illustrated in FIG. 2, a semiconductor substrate 100. In the illustrated example, the semiconductor substrate 100 has four memory cell array regions R_{MCA} arranged in the X-direction and the Y-direction. The four memory cell array regions R_{MCA} each include a plurality of finger structure FS arranged in the Y-direction. The semiconductor substrate 100 has an end portion in the Y-direction having a peripheral region R_{P}.

### [Finger Structure FS]

The finger structure FS includes, for example, as illustrated in FIG. 3, a plurality of string units SU arranged in the Y-direction. Between two finger structures FS adjacent in the Y-direction, an inter-finger structure ST is disposed. Between two string units SU adjacent in the Y-direction, an insulating member SHE is disposed.

In this embodiment, one finger structure FS functions as one memory block BLK (FIG. 1). Each of the finger structures FS includes five string units SU. However, a plurality of the finger structures FS may function as one memory block BLK. The finger structure FS may include two to four string units SU, and may include six or more string units SU.

For example, as illustrated in FIG. 4, the finger structure FS includes a plurality of conductive layers 110 arranged in the Z-direction, a plurality of semiconductor columns 120 extending in the Z-direction, and a plurality of gate insulating films 130 disposed between the plurality of conductive layers 110 and each of the plurality of semiconductor columns 120. The semiconductor column 120 has an upper end connected to the semiconductor member 126, the semiconductor member 126 has an upper surface connected to a contact electrode Ch, the contact electrode Ch has an upper end connected to a contact electrode Vy, and the contact electrode Vy has an upper end connected to the bit line BL.

### [Conductive Layer 110]

The conductive layer 110 extends in the X-direction. The conductive layer 110 may include, for example, a stacked film of a barrier conductive film of titanium nitride (TiN) or the like and a metal film of tungsten (W) or the like. The conductive layer 110 may include, for example, polycrystalline silicon containing impurities, such as phosphorus (P) or boron (B). Between the plurality of conductive layers 110 arranged in the Z-direction, insulating layers 101 of silicon oxide (SiO₂) or the like are disposed. Above the plurality of conductive layers 110 arranged in the Z-direction, an insulating layer 102 of silicon oxide (SiO₂) or the like, an insulating layer 103 of silicon nitride (SiN) or the like, and an insulating layer 104 of silicon oxide (SiO₂) or the like are disposed.

Below the conductive layers 110, a conductive layer 112 is disposed. The conductive layer 112 may include, for example, polycrystalline silicon containing impurities, such as phosphorus (P) or boron (B). At a lower surface of the conductive layer 112, for example, a conductive layer of a metal, such as tungsten (W), tungsten silicide, or the like, or another conductive layer may be disposed. Between the conductive layer 112 and the conductive layer 110, an insulating layer 101 of silicon oxide (SiO₂) or the like is disposed.

The conductive layer 112 functions as the source line SL (FIG. 1). The source line SL is disposed, for example, to be common to all the finger structures FS included in the memory cell array region R_{MCA} (FIG. 2).

Among the plurality of conductive layers 110, one or a plurality of the conductive layers 110 positioned at the lowermost layer function as the source-side select gate line SGSB and the gate electrodes of the plurality of source-side select transistors STSB (FIG. 1) connected to the source-side select gate line SGSB. In the following description, such a conductive layer 110 is referred to as the conductive layer 110 (SGSB) in some cases. The conductive layer 110 (SGSB) is electrically independent for each finger structure FS. Each of the conductive layers 110 (SGSB) is provided with a plurality of through-holes corresponding to the plurality of semiconductor columns 120. These plurality of through-holes have inner peripheral surfaces each surrounding an outer peripheral surface of the corresponding semiconductor column 120 over the whole circumference and each opposed to the outer peripheral surface of the corresponding semiconductor column 120.

One or a plurality of the conductive layers 110 positioned above the conductive layer 110 (SGSB) function as the source-side select gate line SGS and gate electrodes of the plurality of source-side select transistors STS (FIG. 1) connected to the source-side select gate line SGS. In the following description, such a conductive layer 110 is referred to as the conductive layer 110 (SGS) in some cases. The conductive layer 110 (SGS) is electrically independent for each finger structure FS. Each of the conductive layers 110 (SGS) is provided with a plurality of through-holes corresponding to the plurality of semiconductor columns 120. These plurality of through-holes have inner peripheral surfaces each surrounding an outer peripheral surface of the corresponding semiconductor column 120 over the whole circumference and each opposed to the outer peripheral surface of the corresponding semiconductor column 120.

A plurality of the conductive layers 110 positioned above the conductive layer 110 (SGS) function as the word lines WL and gate electrodes of a plurality of the memory cells MC (FIG. 1) connected to the word lines WL. In the following description, such a conductive layer 110 is referred to as the conductive layer 110 (WL) in some cases. Each of the conductive layers 110 (WL) is electrically independent for each finger structure FS. Each of the conductive layers 110 (WL) is provided with a plurality of through-holes corresponding to the plurality of semiconductor columns 120. These plurality of through-holes have inner peripheral surfaces each surrounding an outer peripheral surface of the corresponding semiconductor column 120 over the whole circumference and each opposed to the outer peripheral surface of the corresponding semiconductor column 120.

One or a plurality of the conductive layers 110 positioned above the conductive layer 110 (WL) function as the drain-side select gate line SGD and gate electrodes of a plurality of the drain-side select transistors STD (FIG. 1) connected to the drain-side select gate line SGD. In the following description, such a conductive layer 110 is referred to as the conductive layer 110 (SGD) in some cases. FIG. 3 illustrates a conductive layer 110 (SGDT) described later. The conductive layer 110 (SGD) has a shape similar to that of the conductive layer 110 (SGDT). That is, as illustrated in FIG. 3, between two conductive layers 110 (SGD) adjacent in the Y-direction, the insulating member SHE is disposed. Each of the conductive layers 110 (SGD) is electrically independent for each string unit SU.

As illustrated in FIG. 3, a length Y_{SGD} in the Y-direction of the conductive layer 110 (SGD) is smaller than a length Y_{WL} in the Y-direction of the conductive layer 110 (WL). For example, in the example of FIG. 3, for one conductive layer 110 (WL), five conductive layers 110 (SGD) arranged in the Y-direction and four insulating members SHE arranged in the Y-direction are disposed. Therefore, in the example of the drawing, the length Y_{SGD} in the Y-direction of the conductive layer 110 (SGD) is smaller than ⅕ of the length Y_{WL} in the Y-direction of the conductive layer 110 (WL). However, among the five conductive layers 110 (SGD) arranged in the Y-direction corresponding to one finger structure FS, the first and fifth conductive layers 110 (SGD) counting from one side in the Y-direction may have the lengths in the Y-direction larger than the length Y_{SGD} in the Y-direction of the other three conductive layers 110 (SGD), or ⅕ or more of the length Y_{WL} in the Y-direction of the conductive layer 110 (WL).

Each of the conductive layers 110 (SGD) is provided with a plurality of through-holes 113 corresponding to a plurality of semiconductor columns 120 and a plurality of recessed portions 114 corresponding to a plurality of semiconductor columns 120. The plurality of through-holes 113 have inner peripheral surfaces each surrounding an outer peripheral surface of the corresponding semiconductor column 120 over the whole circumference and each opposed to the outer peripheral surface of the corresponding semiconductor column 120. Each of the plurality of recessed portions 114 is connected to a side surface 115 in the Y-direction of the conductive layer 110 (SGD), and opposed to a part of the outer peripheral surface of the corresponding semiconductor column 120.

One or a plurality of the conductive layers 110 positioned above the conductive layers 110 (SGD) function as the drain-side select gate line SGDT and gate electrodes of the plurality of drain-side select transistors STDT (FIG. 1) connected to the drain-side select gate line SGDT. In the following description, such a conductive layer 110 is referred to as the conductive layer 110 (SGDT) in some cases. The conductive layer 110 (SGDT) is basically configured similarly to the conductive layer 110 (SGD). However, the plurality of conductive layers 110 (SGDT) included in one finger structure FS are mutually electrically connected via a wiring or the like.

### [Semiconductor Column 120]

For example, as illustrated in FIG. 3, the semiconductor columns 120 are arranged in the X-direction and the Y-direction in a predetermined pattern. For example, the finger structure FS includes twenty semiconductor column rows SC provided from one side in the Y-direction to the other side in the Y-direction. Each of the twenty semiconductor column rows SC includes a plurality of the semiconductor columns 120 arranged in the X-direction. These twenty semiconductor column rows SC are arranged in the Y-direction at pitches P_{SC}. That is, when focusing on the two semiconductor column rows SC adjacent in the Y-direction, a center position Y_{SC} of one semiconductor column row SC in the Y-direction and a center position Y_{SC} of the other semiconductor column row SC in the Y-direction are spaced in the Y-direction by a distance equal to the pitch P_{SC}.

Note that the pitch P_{SC} can be defined by various kinds of methods.

For example, an XY cross-sectional surface corresponding to the conductive layer 110 (WL) as exemplarily illustrated in FIG. 3 is observed by means, such as a SEM and a TEM, the center positions Y_{SC} in the Y-direction of the twenty semiconductor column rows SC corresponding to the focused finger structure FS are measured on this XY cross-sectional surface, nineteen distances corresponding to these twenty center positions Y_{SC} are measured, and an average value or a medium value of these nineteen distances may be used as the pitch P_{SC}. For example, on this XY cross-sectional surface, the center positions Y_{SC} in the Y-direction of four semiconductor column rows SC corresponding to the focused string unit SU are measured, three distances corresponding to these four center positions Y_{SC} are measured, and an average value or a medium value of these three distances may be used as the pitch P_{SC}.

The center position Y_{SC} of the semiconductor column row SC in the Y-direction can be defined by various kinds of methods. For example, an XY cross-sectional surface as exemplarily illustrated in FIG. 3 is observed by means, such as a SEM and a TEM, a center position in the Y-direction of at least one semiconductor column 120 included in the focused semiconductor column row SC is measured on this XY cross-sectional surface, and any one of the center positions, an average value of a plurality of the center positions, or a medium value of the plurality of center positions may be used as the center position Y_{SC} of the semiconductor column row SC in the Y-direction. The center position in the Y-direction of the semiconductor column 120 may be a position in the Y-direction at a center point of a circumscribed circle of the semiconductor column 120 on this XY cross-sectional surface or may be a position of a centroid in the Y-direction of an image of the semiconductor column 120.

The semiconductor columns 120 corresponding to 4n-th (n is an integer of one or more and four or less) and 4n+1-th semiconductor column rows SC counted from one side in the Y-direction are hereinafter referred to as semiconductor columns 120_{O} in some cases. The semiconductor columns 120 corresponding to first to third, 4n+2-th, 4n+3-th, and 20-th semiconductor column rows SC counted from the one side in the Y-direction are referred to as semiconductor columns 120_{I} in some cases.

The semiconductor column 120, for example, includes polycrystalline silicon (Si) and the like. The semiconductor column 120 has, for example, as illustrated in FIG. 4, an approximately cylindrical shape and has a center portion having an insulating layer 127 of, for example, silicon oxide (SiO₂).

The semiconductor column 120 has a region 121 disposed at its lower end, a region 122 opposed to the one or plurality of conductive layers 110 (SGSB) and the one or plurality of conductive layers 110 (SGS), a region 123 opposed to the plurality of conductive layers 110 (WL), a region 124 opposed to the one or plurality of conductive layers 110 (SGD), and a region 125 opposed to the one or plurality of conductive layers 110 (SGDT).

The region 121 includes N-type impurities, such as phosphorus (P). The region 121 has an approximately cylindrical shape. The region 121 is connected to the conductive layer 112.

The region 122 functions as channel regions of the source-side select transistors STSB, STS. The region 122 has a lower end portion that may include N-type impurities, such as phosphorus (P). The other portion of the region 122 does not necessarily include the N-type impurities, such as phosphorus (P). The region 122 has an approximately cylindrical shape.

The region 123 functions as channel regions of the memory cells MC. The region 123 does not necessarily include N-type impurities, such as phosphorus (P). The region 123 has an approximately cylindrical shape.

The regions 121, 122, 123 of the semiconductor column 1201 are disposed at positions not overlapping with the insulating member SHE when viewed in the Z-direction. On the other hand, each of the regions 121, 122, 123 of the semiconductor column 120_{O} has a portion disposed at a position overlapping with the insulating member SHE when viewed in the Z-direction.

The region 124 functions as a channel region of the drain-side select transistor STD. The region 124 does not necessarily include N-type impurities, such as phosphorus (P).

Here, in the example in FIG. 3, the semiconductor column 120_{I} is spaced from the insulating member SHE. The region 124 of the semiconductor column 120: has an approximately cylindrical shape. The region 124 of the semiconductor column 120_{I} has an outer peripheral surface opposed to the inner peripheral surface of the above-described through-hole 113 provided in the conductive layer 110 (SGD).

In the example in FIG. 3, the semiconductor column 120_{O} is in contact with the insulating member SHE. The region 124 of the semiconductor column 120_{O} may have an approximately cylindrical shape, or may have an arc shape when viewed in the Z-direction. A part of the region on the outer peripheral surface of the region 124 of the semiconductor column 120_{O} is opposed to the above-described recessed portion 114 provided in the conductive layer 110 (SGD). The other region on the outer peripheral surface of the region 124 of the semiconductor column 120_{O} is in contact with the insulating member SHE.

The region 125 (FIG. 4) functions as a channel region of the drain-side select transistor STDT. The region 125 has an upper end portion that may include N-type impurities, such as phosphorus (P). The other portion of the region 125 does not necessarily include N-type impurities, such as phosphorus (P). The region 125 of the semiconductor column 120: has an approximately cylindrical shape. The region 125 of the semiconductor column 120_{O} may have an approximately cylindrical shape or may have an arc shape when viewed in the Z-direction.

### [Semiconductor Member 126]

The semiconductor member 126 (FIG. 4) includes N-type impurities, such as phosphorus (P). As illustrated in FIG. 8, the semiconductor member 126 connected to the semiconductor column 120_{I} (hereinafter referred to as a “semiconductor member 126_{I}” in some cases) is formed in an approximately columnar shape. On the other hand, the semiconductor member 126 connected to the semiconductor column 120_{O} (hereinafter referred to as a “semiconductor member 126_{O}” in some cases) is formed in a columnar shape with a missing part. That is, a part of the outer peripheral surface of the semiconductor member 126, is formed along a circle having a size similar to that of a circumscribed circle of the semiconductor member 1261. On the other hand, a part of the outer peripheral surface of the semiconductor member 1260 at the insulating member SHE side in the Y-direction forms a recessed portion 126A. A length Y₁₂₆ in the Y-direction of the semiconductor member 1260 is smaller than a length X₁₂₆ in the X-direction of the semiconductor member 1260.

FIG. 6 illustrates three points p1 to p3 on the recessed portion 126A. The points p1, p2 are spaced in the Z-direction. A position in the Z-direction of the point p3 is provided between a position in the Z-direction of the point p1 and a position in the Z-direction of the point p2. The point p3 is provided in an opposite side of the insulating member SHE in the Y-direction with respect to the points p1, p2.

FIG. 8 illustrates three points p4 to p6 on the recessed portion 126A. The points p4, p5 are spaced in the X-direction. A position in the X-direction of the point p6 is provided between a position in the X-direction of the point p4 and a position in the X-direction of the point p5. The point p6 is provided in an opposite side of the insulating member SHE in the Y-direction with respect to the points p4, p5.

### [Gate Insulating Film 130]

The gate insulating film 130 has an approximately cylindrical shape covering the outer peripheral surfaces of the semiconductor column 120 and the semiconductor member 126. The gate insulating film 130 includes a tunnel insulating film 131, an electric charge accumulating film 132, and a block insulating film 133 stacked between the semiconductor column 120 and the conductive layer 110, for example, as illustrated in FIG. 5. The tunnel insulating film 131 and the block insulating film 133 include, for example, silicon oxide (SiO₂) or the like. The electric charge accumulating film 132 is, for example, a film of silicon nitride (SiN) or the like that can accumulate electric charge. The tunnel insulating film 131, the electric charge accumulating film 132, and the block insulating film 133 have an approximately cylindrical shape and extend in the Z-direction along the outer peripheral surface of the semiconductor column 120 excluding a part of the region. For example, as illustrated in FIG. 4, at a contact portion between the semiconductor column 120 and the conductive layer 112, the tunnel insulating film 131, the electric charge accumulating film 132, and the block insulating film 133 are not disposed. At a contact surface of the semiconductor column 120_{O} with the insulating member SHE, the tunnel insulating film 131, the electric charge accumulating film 132, and the block insulating film 133 are not necessarily disposed.

Note that FIG. 5 illustrates the example in which the gate insulating film 130 includes the electric charge accumulating film 132 of, for example, silicon nitride. However, the gate insulating film 130 may, for example, include a floating gate of, for example, polycrystalline silicon containing N-type or P-type impurities.

### [Contact Electrode Ch]

The contact electrode Ch extends in the Z-direction passing through a part of the insulating layer 104, the insulating layer 103, and a part of the insulating layer 102. The contact electrode Ch may include, for example, a stacked film of a barrier conductive film of titanium nitride (TiN) or the like and a metal film of tungsten (W) or the like. For example, as illustrated in FIG. 3, the contact electrodes Ch are arranged in the X-direction and the Y-direction in a predetermined pattern corresponding to the semiconductor columns 120.

As illustrated in FIG. 3 and FIG. 4, the contact electrode Ch connected to the semiconductor member 126 (hereinafter referred to as a “contact electrode Ch_{I}” in some cases) is formed in an approximately columnar shape. The contact electrode Ch_{I} has a lower end entirely in contact with an upper surface of the semiconductor member 1261.

As illustrated in FIG. 6 and FIG. 7, the contact electrode Ch connected to the semiconductor member 1260 (hereinafter referred to as a “contact electrode Ch_{O}” in some cases) includes a conductive region R_{Ch1} provided above the upper surface of the semiconductor member 126 and a conductive region R_{Ch2} provided below the upper surface of the semiconductor member 126.

The conductive region R_{Ch1} is formed in an approximately columnar shape extending in the Z-direction. The conductive region R_{Ch1} has a lower end partially in contact with an upper surface of the semiconductor member 1260.

The conductive region R_{Ch2} is provided between the semiconductor member 1260 and an insulating member 151 described later or an insulating member 152 described later. The conductive region R_{Ch2} has a lower end provided below the upper surface of the semiconductor member 126 and above a lower surface of the semiconductor member 126 (upper end of the insulating layer 127). The lower end and a side surface on one side in the Y-direction of the conductive region R_{Ch2} are in contact with the insulating member 151, 152, and covered with the insulating member 151, 152. A side surface on the other side in the Y-direction of the conductive region R_{Ch2} is in contact with the recessed portion 126A of the semiconductor member 126, and covered with the recessed portion 126A.

As illustrated in FIG. 6 and FIG. 7, the contact electrode Ch has an outer peripheral surface provided with an insulating film 157 of silicon oxide (SiO₂) or the like. The insulating film 157 has an approximately cylindrical shape, and extends in the Z-direction along the outer peripheral surface of the contact electrode Ch.

### [Insulating Member SHE]

For example, as illustrated in FIG. 3 and FIG. 4, the insulating member SHE extends in the X-direction and the Z-direction. The insulating member SHE includes, for example, silicon oxide (SiO₂).

A length Y_{SHE} (FIG. 8) in the Y-direction of the insulating member SHE is smaller than the length Y_{SGD} in the Y-direction (FIG. 3) of the conductive layer 110 (SGD) and the conductive layer 110 (SGDT). The length Y_{SHE} (FIG. 8) of the insulating member SHE in the Y-direction is smaller than the pitch P_{SC} (FIG. 3) of the plurality of semiconductor column rows SC in the Y-direction. While the insulating member SHE is disposed between the semiconductor columns 1200 included in the two semiconductor column rows SC adjacent in the Y-direction, the insulating member SHE itself is not provided with the through-hole or the recessed portion corresponding to the semiconductor column 120.

As illustrated in FIG. 6 and FIG. 7, the insulating member SHE has a lower end positioned above a lower surface of the conductive layer 110 (WL) positioned at the uppermost layer. The lower end of the insulating member SHE is positioned below a lower surface of the conductive layer 110 (SGD) positioned at the lowermost layer. The insulating member SHE has an upper end in contact with a lower surface of the insulating layer 103.

The insulating member SHE includes a region R1 provided below a height position Z3 described later and a region R2 provided above the height position Z3. In the example of the drawing, the height position 23 is provided below the lower surface of the semiconductor member 126 (upper end of the insulating layer 127). This height position Z3 corresponds to height positions of lower ends of the insulating members 151, 152 described later.

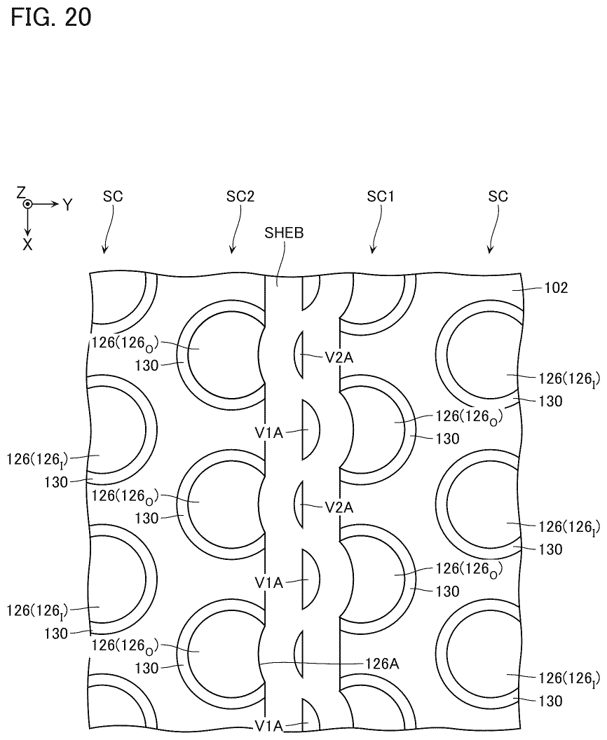

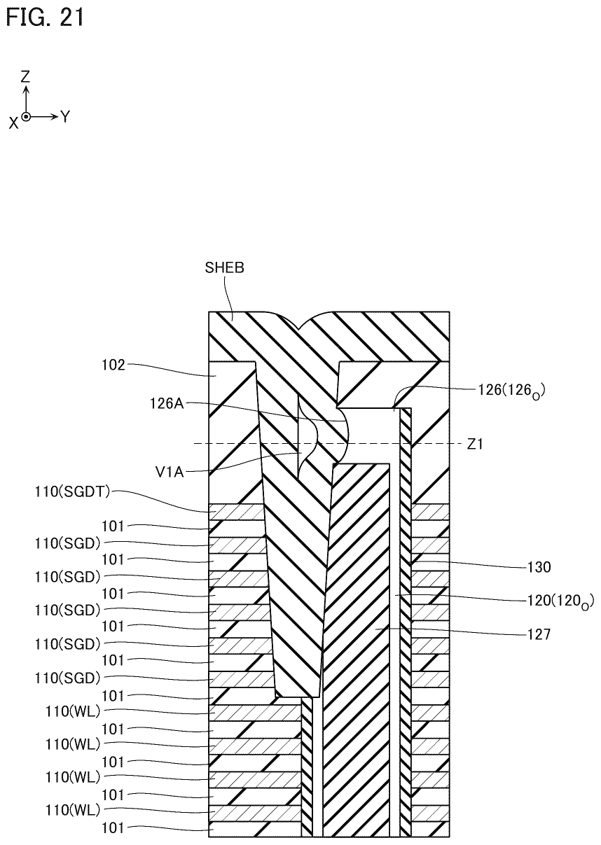

The region R1 is gaplessly filled with a material achieved from a part of an insulating layer SHEB described later with reference to FIG. 20 and FIG. 21. That is, the region R1 is not internally provided with a cavity, a conductive member, another insulating member, or the like. A length in the Z-direction of the region R1 (length from the lower ends of the insulating members 151, 152 to the lower end of the insulating member SHE) is larger than a half of the length Y_{SHE} (FIG. 8) in the Y-direction of the insulating member SHE.

The region R2 formed of the material achieved from a part of the insulating layer SHEB (FIG. 20, FIG. 21) described later similarly to the region R1 is internally provided with a region R3 not including the material achieved from a part of the insulating layer SHEB. The region R3 is provided at the height position Z1 corresponding to the semiconductor member 126 and a proximity of the height position Z1. The region R3 internally includes the insulating members 151, 152 illustrated in FIG. 6 to FIG. 8.

### [Insulating Members 151, 152]

FIG. 8 illustrates two semiconductor column rows SC1, SC2 adjacent in the Y-direction. These two semiconductor column rows SC1, SC2 are two of the plurality of semiconductor column rows SC described with reference to FIG. 3. FIG. 8 also illustrates the insulating member SHE disposed between these two semiconductor column rows SC1, SC2, a plurality of the insulating members 151 arranged in the X-direction corresponding to the plurality of semiconductor columns 120 included in the semiconductor column row SC1, and a plurality of the insulating members 152 arranged in the X-direction corresponding to the plurality of semiconductor columns 120 included in the semiconductor column row SC2. The plurality of insulating members 151, 152 are each provided at the height position Z1 corresponding to the semiconductor member 126 and the proximity of the height position Z1.

In the cross-sectional surface illustrated in FIG. 6, the insulating member 151 is surrounded by the insulating member SHE, the contact electrode Ch, and the semiconductor member 126. The insulating member 151 contains, for example, silicon oxide (SiO₂). The insulating member 151 is connected to the insulating film 157. The insulating member 151 includes insulating portions 153, 154.

The insulating portion 153 of the insulating member 151 has an upper end, a lower end, a side surface on the opposite side of the semiconductor column row SC1 in the Y-direction, and a part of a side surface on a semiconductor column row SC1 side in the Y-direction (portion corresponding to a height region from a lower end of the insulating portion 153 to a lower surface of the insulating portion 154) in contact with the insulating member SHE and formed along the insulating member SHE. The insulating portion 153 has a part of the side surface at the semiconductor column row SC1 side in the Y-direction (portion corresponding to a height region from a lower end of the contact electrode Ch to an upper end of the insulating portion 153) in contact with the contact electrode Ch and formed along the contact electrode Ch.

At the height position Z1 inside the insulating portion 153, a cavity V1 is provided. In the example of FIG. 6, a height position Z2 corresponding to a lower end of the cavity V1 and a height position Z4 corresponding to an upper end of the cavity V1 are provided above the lower surface of the semiconductor member 126 and below the upper surface of the semiconductor member 126. However, the height position Z2 may be provided below the lower surface of the semiconductor member 126. The height position Z4 may be provided above the upper surface of the semiconductor member 126.

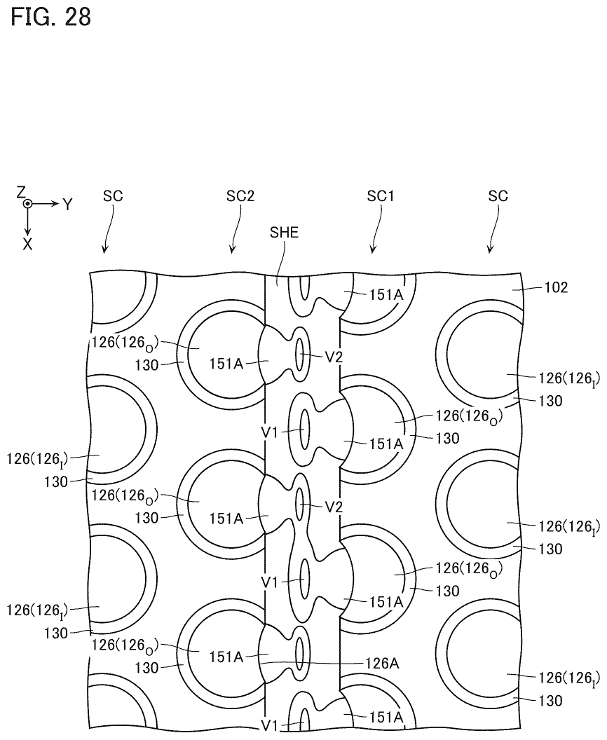

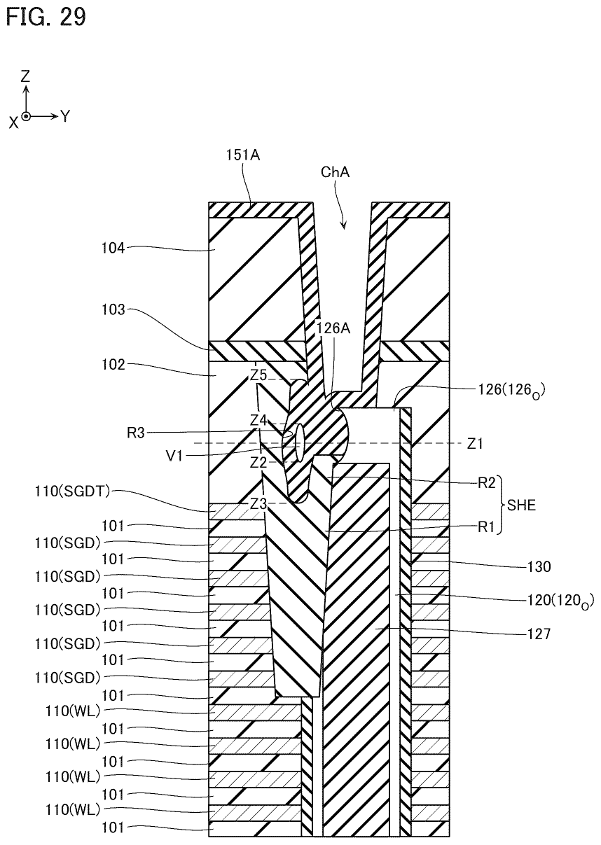

The cavity V1 is spaced from the contact electrode Ch via a part of the insulating portion 153. A portion provided above the height position Z4 and a portion provided below the height position Z2 of the insulating portion 153 are gaplessly filled with a material achieved from parts of an insulating member 151A described later with reference to FIG. 28 and FIG. 29. That is, these portions are not provided with a cavity, a conductive member, another insulating member, or the like. Similarly, end portions of the insulating portion 153 on one side and the other side in the X-direction are gaplessly filled with a material achieved from parts of the insulating members 151A described later. That is, these portions are also not provided with a cavity, a conductive member, another insulating member, or the like.

In the example of FIG. 6, a height position Z5 corresponding to the upper end of the insulating portion 153 is provided above the upper surface of the semiconductor member 126 and below the upper end of the insulating member SHE. However, the height position Z5 may be provided below the upper surface of the semiconductor member 126. A height position Z3 corresponding to the lower end of the insulating portion 153 is provided below the lower surface of the semiconductor member 126 and above the lower end of the insulating member SHE. In the example of the drawing, the height position Z3 is provided above with respect to an upper surface of the uppermost conductive layer 110. However, the height position Z3 may be provided above the lower surface of the semiconductor member 126, or may be provided below the upper surface of the uppermost conductive layer 110. In the example of the drawing, a length from the lower end of the insulating portion 153 to the lower end of the insulating member SHE is larger than a length from the upper end of the insulating portion 153 to the upper end of the insulating member SHE.

The insulating portion 154 of the insulating member 151 is disposed at a position overlapping with the conductive region R_{Ch2} of the contact electrode Ch when viewed in the Z-direction. The insulating portion 154 has an upper surface in contact with a lower surface of the conductive region R_{Ch2} of the contact electrode Ch and formed along the lower surface of the conductive region R_{Ch2} of the contact electrode Ch. The insulating portion 154 has a side surface in the Y-direction in contact with the semiconductor member 126 and formed along the semiconductor member 126. The insulating portion 154 has a lower surface in contact with the insulating member SHE and formed along the insulating member SHE.

In the example of FIG. 6, the upper surface and the lower surface of the insulating portion 154 are provided between the upper surface and the lower surface of the semiconductor member 126.

A length in the Y-direction of the insulating member 151 becomes maximum in a height range corresponding to the insulating portion 154 (hereinafter referred to as a “first height range”). The length in the Y-direction of the insulating member 151 in a height range corresponding to a range from the upper surface of the insulating portion 154 to the upper end of the insulating member 151 (hereinafter referred to as a “second height range”) is smaller than the length in the Y-direction of the insulating member 151 in the first height range. For example, the length in the Y-direction of the insulating member 151 at the height position Z4 is smaller than the length in the Y-direction of the insulating member 151 at the height position Z1. The length in the Y-direction of the insulating member 151 in a height range corresponding to a range from the lower surface of the insulating portion 154 to the lower end of the insulating member 151 (hereinafter referred to as a “third height range”) is smaller than the length in the Y-direction of the insulating member 151 in the first height range. For example, the length in the Y-direction of the insulating member 151 at the height position Z2 is smaller than the length in the Y-direction of the insulating member 151 at the height position Z1.

In the first height range, the length in the Y-direction of the insulating member 151 becomes maximum at a height position in the Z-direction corresponding to the most recessed part of the recessed portion 126A. The length in the Y-direction of the insulating member 151 decreases as it gets away from this height position. For example, in the first and the second height ranges, the length in the Y-direction of the insulating member 151 decreases upward from this height position. In the first and the third height ranges, the length in the Y-direction of the insulating member 151 decreases downward from this height position.

As illustrated in FIG. 8, the insulating member 151 widens in the Y-direction along the recessed portion 126A. That is, the length in the Y-direction of the insulating member 151 becomes maximum at a position in the X-direction corresponding to the most recessed part of the recessed portion 126A. This position in the X-direction corresponds to, for example, a center position in the X-direction of the semiconductor member 126. The length in the Y-direction of the insulating member 151 decreases as it gets away from this position in the X-direction. Both end portions in the X-direction of the insulating portion 153 are disposed at positions not overlapping with the contact electrode Ch when viewed in the Z-direction.

In the cross-sectional surface illustrated in FIG. 6, a cross-sectional area of the insulating member 151 is smaller than a cross-sectional area of the insulating member SHE.

In the cross-sectional surface illustrated in FIG. 7, the insulating member 152 is surrounded by the insulating member SHE, the contact electrode Ch, and the semiconductor member 126. The insulating member 152 contains, for example, silicon oxide (SiO₂). The insulating member 152 is connected to the insulating film 157. The insulating member 152 includes insulating portions 155, 156.

The insulating portion 155 of the insulating member 152 has an upper end, a lower end, a side surface at the opposite side of the semiconductor column row SC2 in the Y-direction, and a part of a side surface at the semiconductor column row SC2 side in the Y-direction (portion corresponding to a height region from a lower end of the insulating portion 155 to a lower surface of the insulating portion 156) in contact with the insulating member SHE and formed along the insulating member SHE. The insulating portion 155 has a part of the side surface at the semiconductor column row SC2 side in the Y-direction (portion corresponding to a height region from a lower end of the contact electrode Ch to an upper end of the insulating portion 155) in contact with the contact electrode Ch and formed along the contact electrode Ch.

At the height position Z1 inside the insulating portion 155, a cavity V2 is provided. In the example of FIG. 7, a height position Z12 corresponding to a lower end of the cavity V2 and a height position Z14 corresponding to an upper end of the cavity V2 are provided above the lower surface of the semiconductor member 126 and below the upper surface of the semiconductor member 126. However, the height position Z12 may be provided below the lower surface of the semiconductor member 126. The height position Z14 may be provided above the upper surface of the semiconductor member 126.

The cavity V2 is spaced from the contact electrode Ch via a part of the insulating portion 155. A portion provided above height position Z14 and a portion provided below the height position Z12 of the insulating portion 155 are gaplessly filled with a material achieved from parts of an insulating member 151A described later with reference to FIG. 28 and FIG. 29. That is, these portions are not provided with a cavity, a conductive member, another insulating member, or the like. Similarly, end portions of the insulating portion 155 on one side and the other side in the X-direction are gaplessly filled with a material achieved from parts of the insulating member 151A described later. That is, these portions are also not provided with a cavity, a conductive member, another insulating member, or the like.

In the example of FIG. 7, a height position Z15 corresponding to the upper end of the insulating portion 155 is provided above the upper surface of the semiconductor member 126 and below the upper end of the insulating member SHE. However, the height position Z15 may be provided below the upper surface of the semiconductor member 126. A height position Z13 corresponding to the lower end of the insulating portion 155 is provided below the lower surface of the semiconductor member 126 and above the lower end of the insulating member SHE. In the example of the drawing, the height position Z13 is provided above with respect to an upper surface of the uppermost conductive layer 110. However, the height position Z13 may be provided above the lower surface of the semiconductor member 126, or may be provided below the upper surface of the uppermost conductive layer 110. In the example of the drawing, a length from the lower end of the insulating portion 155 to the lower end of the insulating member SHE is larger than a length from the upper end of the insulating portion 155 to the upper end of the insulating member SHE.

The insulating portion 156 of the insulating member 152 is disposed at a position overlapping with the conductive region R_{Ch2} of the contact electrode Ch when viewed in the Z-direction. The insulating portion 156 has an upper surface in contact with a lower surface of the conductive region R_{Ch2} of the contact electrode Ch and formed along the lower surface of the conductive region R_{Ch2} of the contact electrode Ch. The insulating portion 156 has a side surface in the Y-direction in contact with the semiconductor member 126 and formed along the semiconductor member 126. The insulating portion 156 has a lower surface in contact with the insulating member SHE and formed along the insulating member SHE.

In the example of FIG. 7, the upper surface and the lower surface of the insulating portion 156 are provided between the upper surface and the lower surface of the semiconductor member 126.

In the cross-sectional surface illustrated in FIG. 7, a cross-sectional area of the insulating member 152 is smaller than a cross-sectional area of the insulating member SHE.

A length in the Y-direction of the insulating member 152 becomes maximum in a height range corresponding to the insulating portion 156 (hereinafter referred to as a “fourth height range”). The length in the Y-direction of the insulating member 152 in a height range corresponding to a range from the upper surface of the insulating portion 156 to the upper end of the insulating member 152 (hereinafter referred to as a “fifth height range”) is smaller than the length in the Y-direction of the insulating member 152 in the fourth height range. For example, the length in the Y-direction of the insulating member 152 at the height position Z14 is smaller than the length in the Y-direction of the insulating member 152 at the height position Z1. The length in the Y-direction of the insulating member 152 in a height range corresponding to a range from the lower surface of the insulating portion 156 to the lower end of the insulating member 152 (hereinafter referred to as a “sixth height range”) is smaller than the length in the Y-direction of the insulating member 152 in the fourth height range. For example, the length in the Y-direction of the insulating member 152 at the height position Z12 is smaller than the length in the Y-direction of the insulating member 152 at the height position Z1.

In the fourth height range, the length in the Y-direction of the insulating member 152 becomes maximum at a height position in the Z-direction corresponding to the most recessed part of the recessed portion 126A. The length in the Y-direction of the insulating member 152 decreases as it gets away from this height position. For example, in the fourth and the fifth height ranges, the length in the Y-direction of the insulating member 152 decreases upward from this height position. In the fourth and the sixth height ranges, the length in the Y-direction of the insulating member 152 decreases downward from this height position.

As illustrated in FIG. 8, the insulating member 152 widens in the Y-direction along the recessed portion 126A. That is, the length in the Y-direction of the insulating member 152 becomes maximum at a position in the X-direction corresponding to the most recessed part of the recessed portion 126A. This position in the X-direction corresponds to, for example, a center position in the X-direction of the semiconductor member 126. The length in the Y-direction of the insulating member 152 decreases as it gets away from this position in the X-direction. Both end portions in the X-direction of the insulating member 152 are disposed at positions not overlapping with the contact electrode Ch when viewed in the Z-direction.

In the cross-sectional surface illustrated in FIG. 8, the insulating portions 153 of the plurality of insulating members 151 and the insulating portions 155 of the plurality of insulating members 152 are alternately arranged in the X-direction at the proximity of the center position of the insulating member SHE in the Y-direction. In the example of the drawing, a part of the plurality of insulating members 151 are connected to any of the plurality of insulating members 152. The cavity V1 of such an insulating member 151 is spaced from the cavity V2 in the insulating member 152 via a connecting portion between the insulating members 151, 152. A part of the plurality of insulating members 151 are spaced from any of the plurality of insulating members 152. The cavity V1 of such an insulating member 151 is spaced from the cavity V2 of the insulating member 152 via parts of the insulating members 151, 152 and a part of the insulating member SHE.

As described below, the insulating members 151, 152 are formed in a process described with reference to FIG. 28 to FIG. 30 after the insulating member SHE is formed in a process described with reference to FIG. 20 to FIG. 27. Therefore, the insulating members 151, 152 have an etching rate different from that of the insulating member SHE.

### [Inter-Finger Structure ST]

The inter-finger structure ST includes, as illustrated in FIG. 3 and FIG. 4, for example, a conductive layer 141 extending in the X-direction and the Z-direction and insulating layers 142 of silicon oxide (SiO₂) or the like disposed on side surfaces in the Y-direction of the conductive layer 141. The conductive layer 141 has a lower end connected to the conductive layer 112. The conductive layer 141 has an upper end located above the upper surface of the semiconductor member 126 and below a lower surface of the insulating layer 103. The conductive layer 141 may include, for example, a stacked film of a barrier conductive film of titanium nitride (TiN) or the like and a metal film of tungsten (W) or the like. The conductive layer 141 may contain, for example, polycrystalline silicon containing impurities, such as phosphorus (P) or boron (B). The conductive layer 141 functions as, for example, a part of the source line SL (FIG. 1).

### [Bit Line BL]

As illustrated in FIG. 3, the bit lines BL extend in the Y-direction, and are arranged in the X-direction. The bit lines BL have X-direction pitches that are a half of X-direction pitches of the semiconductor columns 120 in the semiconductor column row SC. The bit line BL may include, for example, a stacked film of a barrier conductive film of titanium nitride (TiN) or the like and a metal film of copper (Cu) or the like. The above-described contact electrode Vy is disposed at a position at which the bit line BL overlaps with the contact electrode Ch when viewed in the Z-direction.

### [Manufacturing Method]

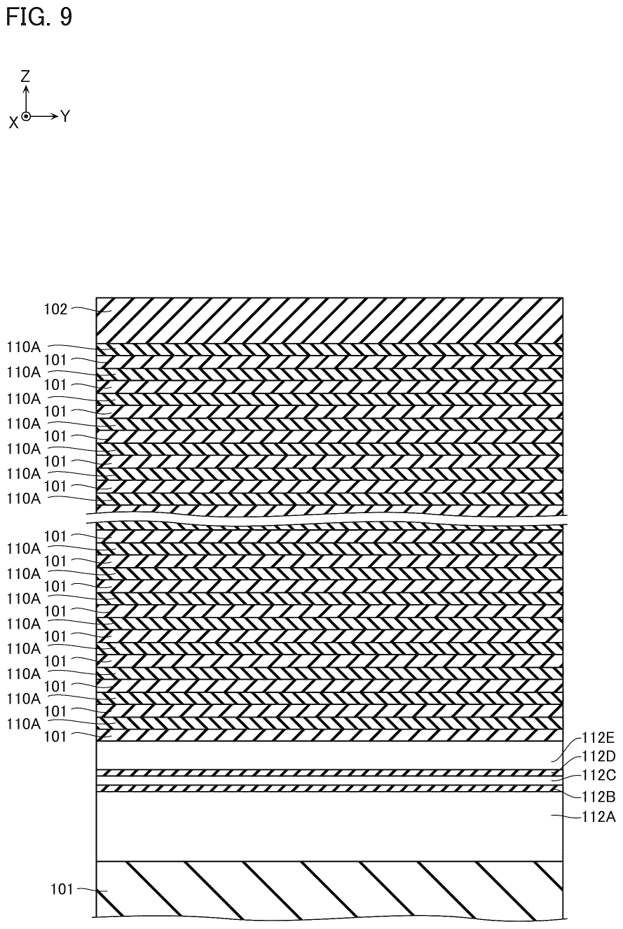

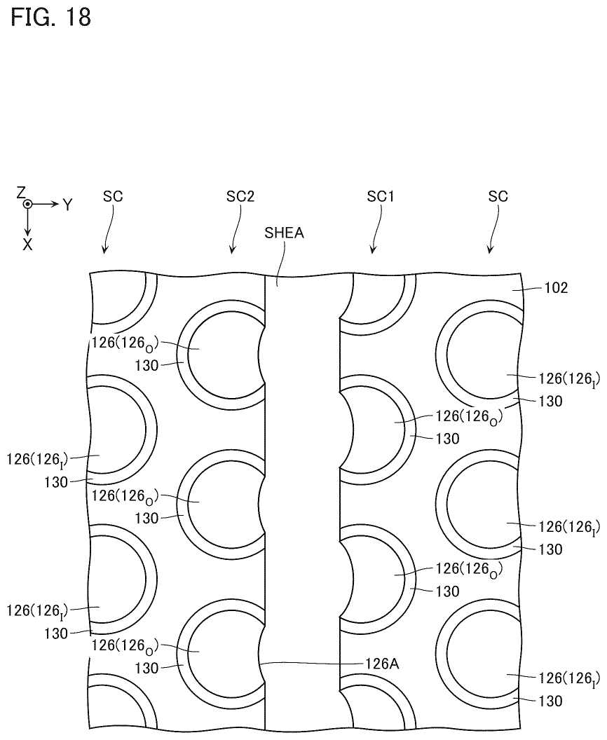

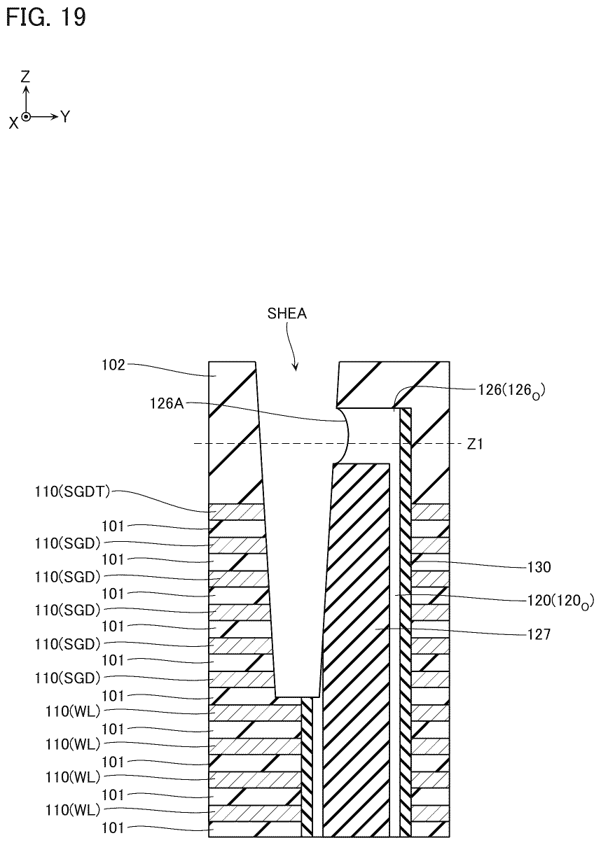

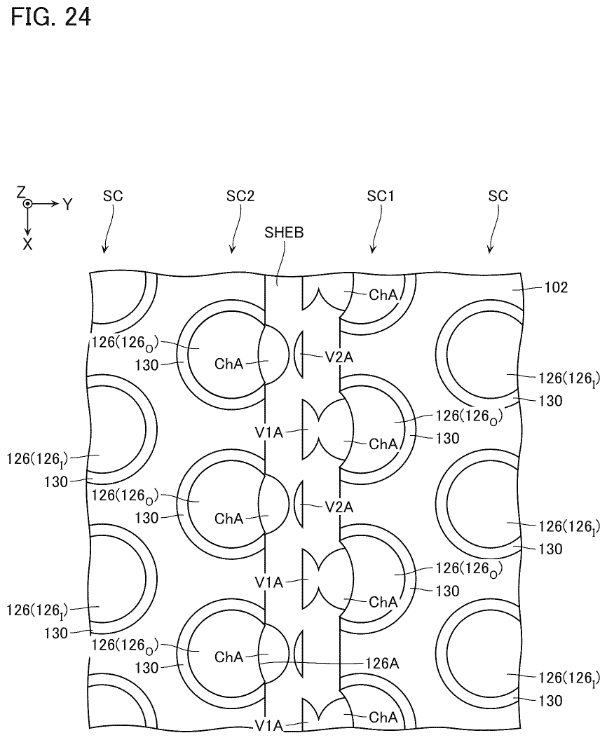

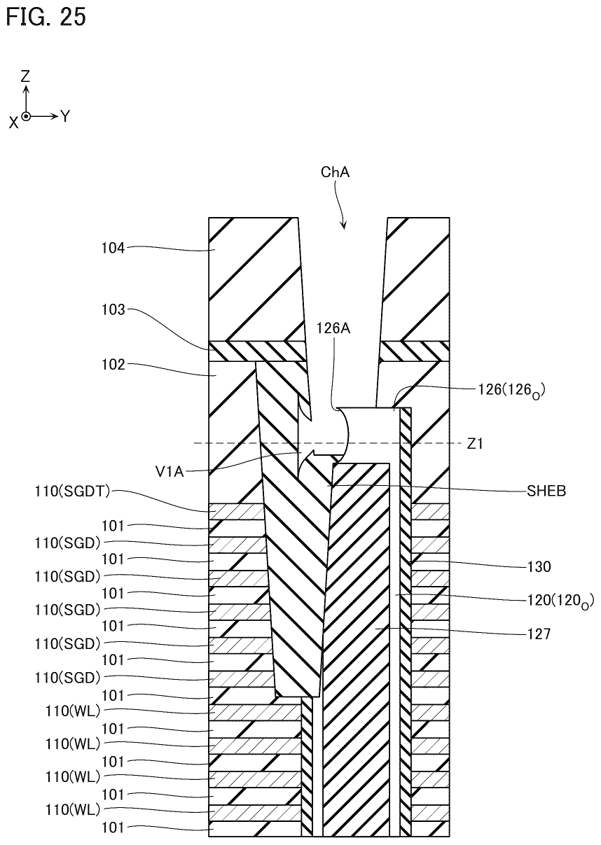

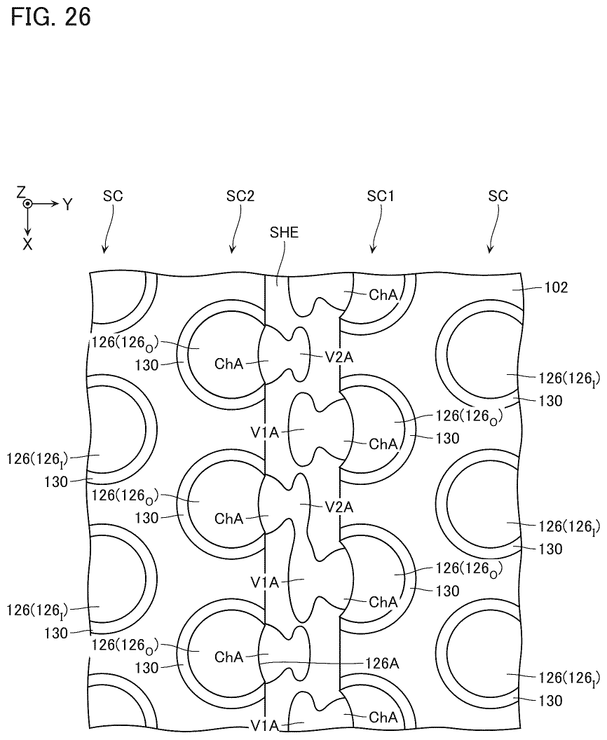

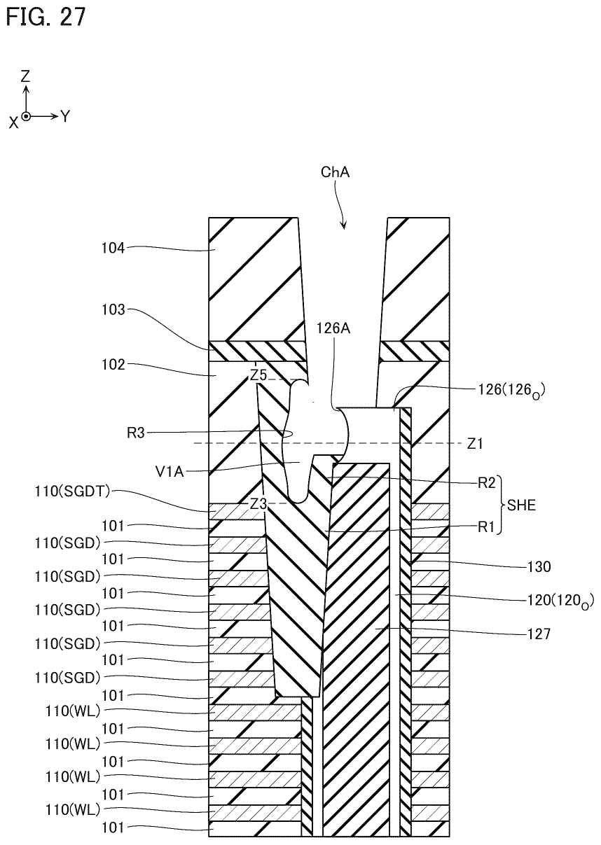

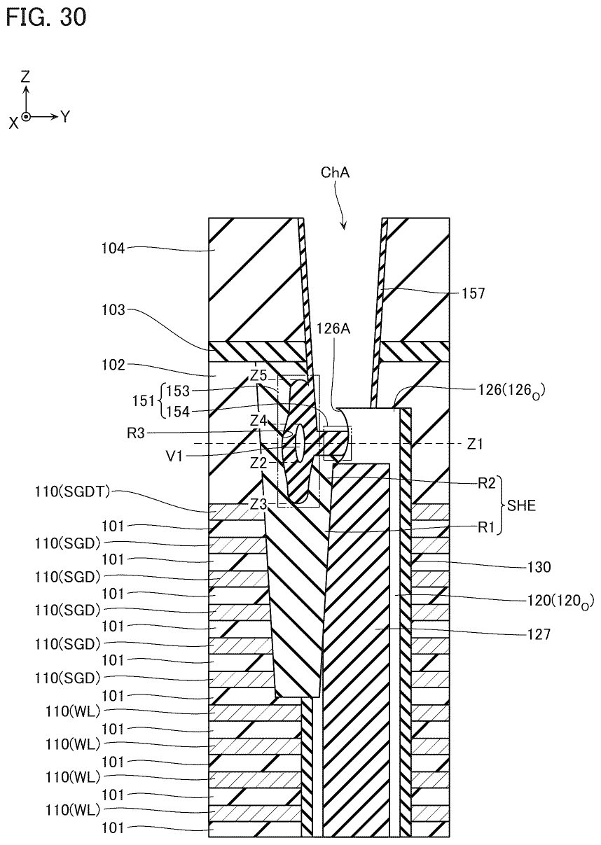

Next, with reference to FIG. 9 to FIG. 30, a method for manufacturing the semiconductor memory device according to the first embodiment is described. FIG. 9 to FIG. 30 are schematic cross-sectional views for describing the manufacturing method. FIG. 9 to FIG. 17 illustrate the cross-sectional surface corresponding to FIG. 4. FIG. 18, FIG. 20, FIG. 24, FIG. 26, and FIG. 28 illustrate the cross-sectional surface corresponding to FIG. 8. FIG. 19, FIG. 21 to FIG. 23, FIG. 25, FIG. 27, FIG. 29, and FIG. 30 illustrate the cross-sectional surface corresponding to FIG. 6.

In the manufacture of the memory die MD according to the embodiment, for example, as illustrated in FIG. 9, the insulating layer 101 is formed above a semiconductor substrate (not illustrated in FIG. 9). Next, a semiconductor layer 112A of silicon or the like, a sacrifice layer 112B of silicon oxide or the like, a sacrifice layer 112C of silicon or the like, a sacrifice layer 112D of silicon oxide or the like, and a semiconductor layer 112E of silicon or the like are formed on the insulating layer 101. A plurality of insulating layers 101 and a plurality of sacrifice layers 110A are alternately formed. A part of the insulating layer 102 is formed. This process is performed by a method, such as Chemical Vapor Deposition (CVD).

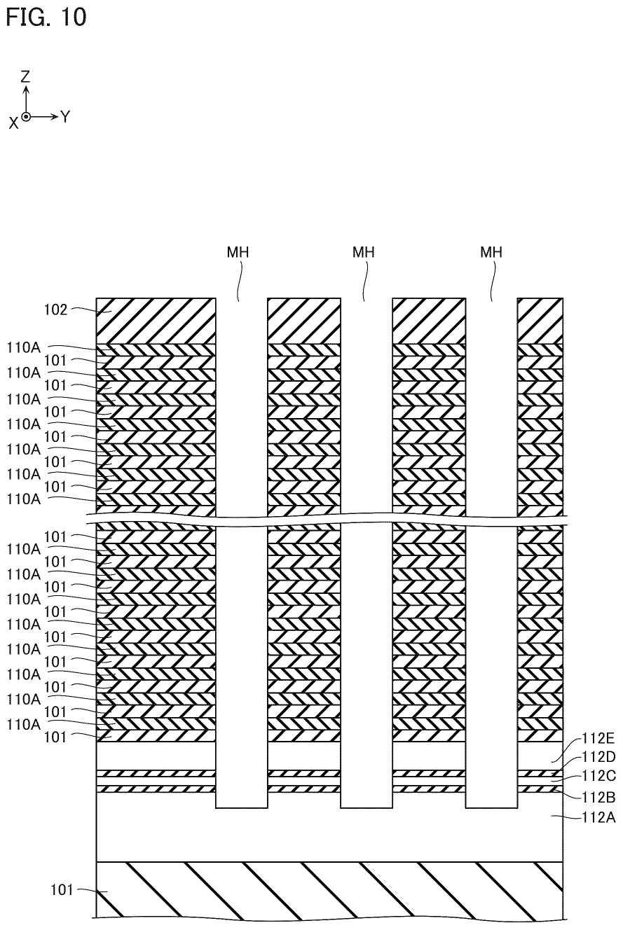

Next, for example, as illustrated in FIG. 10, memory holes MH are formed at positions corresponding to the semiconductor columns 120. The memory hole MH extends in the Z-direction, and penetrates the insulating layer 102, the insulating layers 101 and the sacrifice layers 110A, the semiconductor layer 112E, the sacrifice layer 112D, the sacrifice layer 112C, and the sacrifice layer 112B to expose an upper surface of the semiconductor layer 112A. This process is performed by a method, such as RIE.

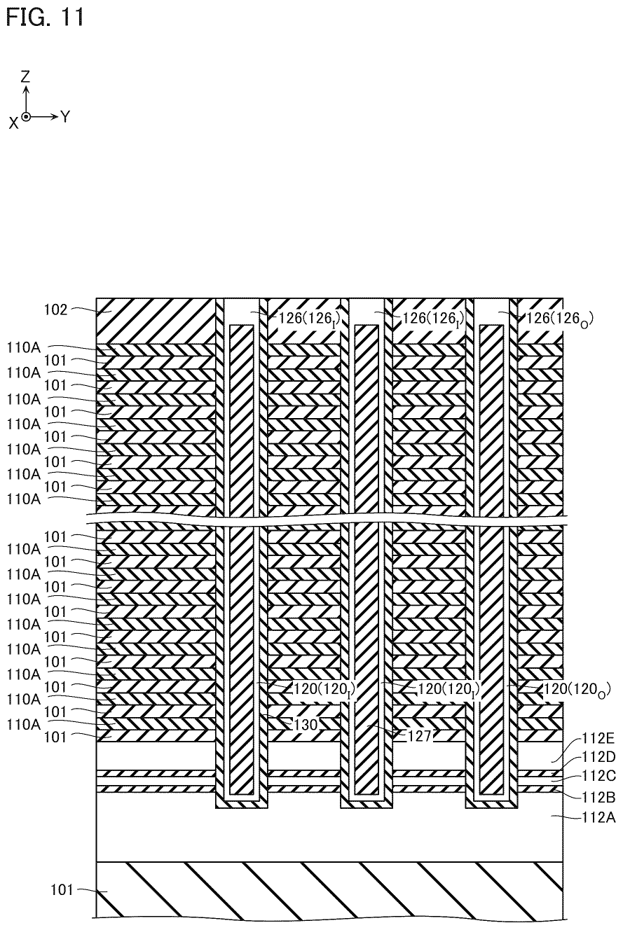

Next, for example, as illustrated in FIG. 11, the gate insulating film 130, the semiconductor column 120, the insulating layer 127, and the semiconductor member 126 are formed inside the memory holes MH. This process is performed by the method, such as CVD.

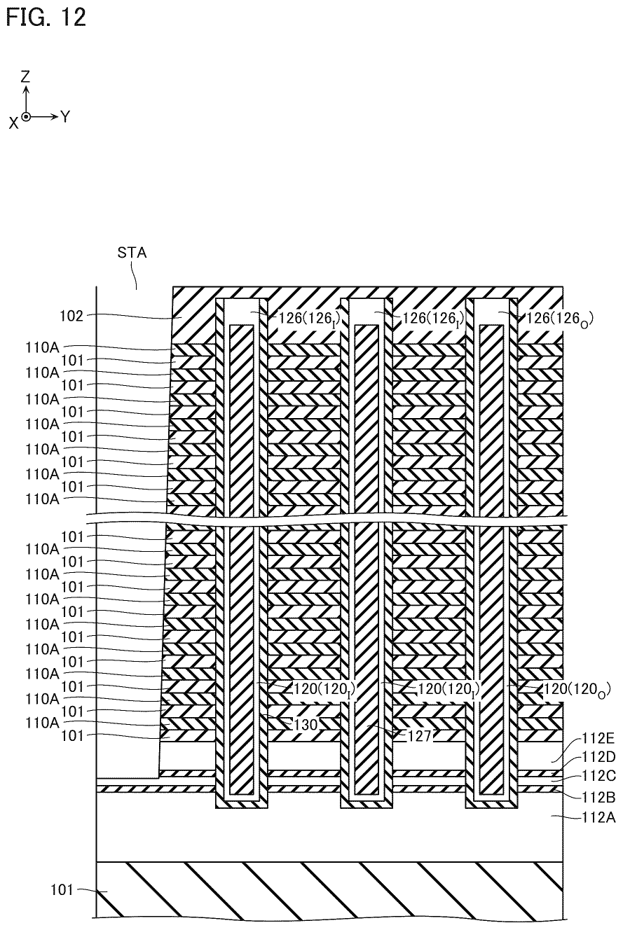

Next, for example, as illustrated in FIG. 12, a part of the insulating layer 102 is formed by the method, such as CVD. Trenches STA are formed at positions corresponding to the inter-finger structures ST. The trench STA extends in the Z-direction and the X-direction, separates the insulating layer 102, the insulating layers 101 and the sacrifice layers 110A, the semiconductor layer 112E, and the sacrifice layer 112D in the Y-direction to expose an upper surface of the sacrifice layer 112C. This process is performed by the method, such as RIE.

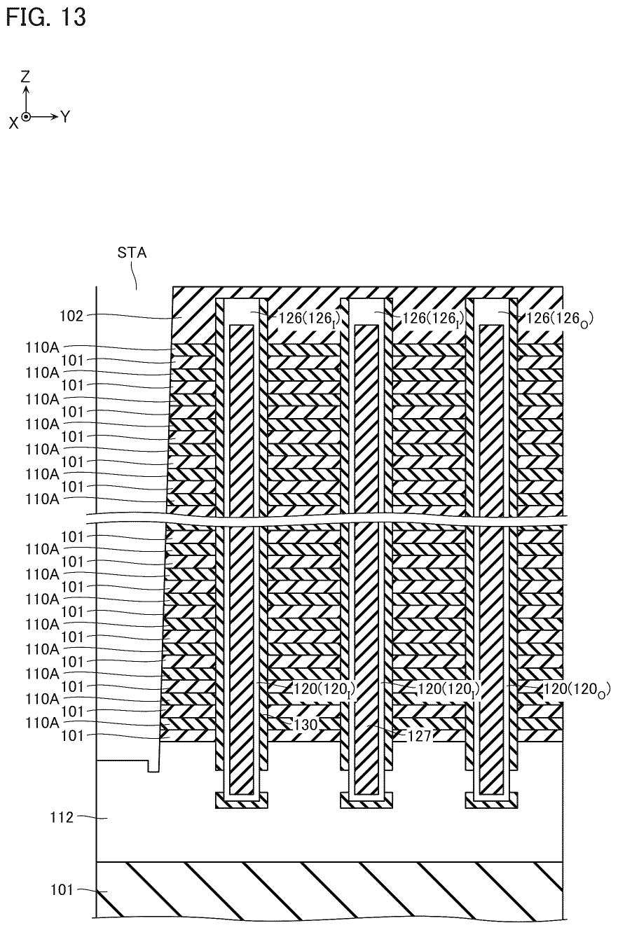

Next, for example, as illustrated in FIG. 13, the sacrifice layer 112B, the sacrifice layer 112C, the sacrifice layer 112D, and the gate insulating film 130 are partially removed to form the conductive layer 112. The partial removal of the sacrifice layer 112B, the sacrifice layer 112C, the sacrifice layer 112D, and the gate insulating film 130 is performed by a method, such as wet etching. The formation of the conductive layer 112 is performed by a method, such as epitaxial growth.

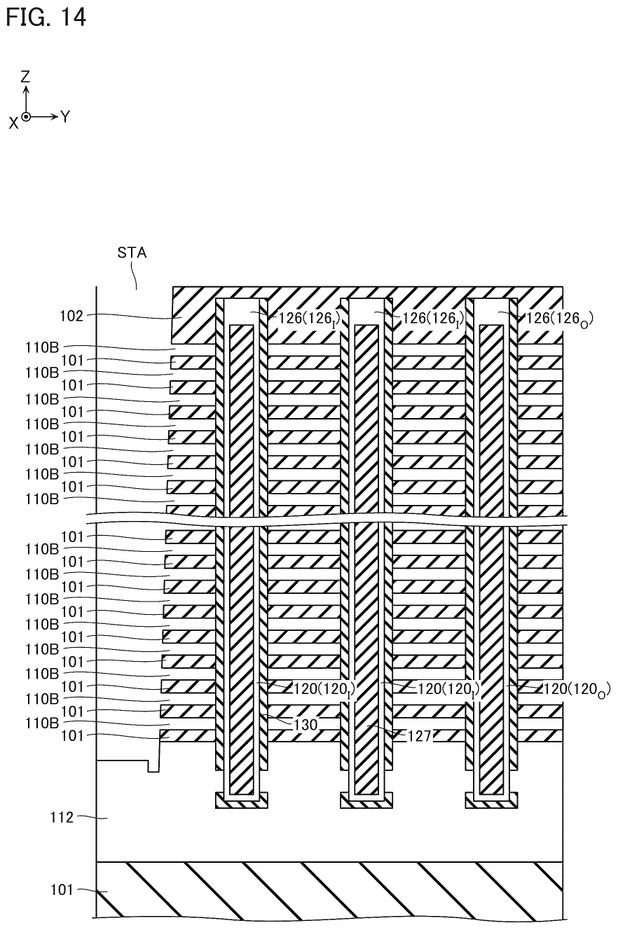

Next, for example, as illustrated in FIG. 14, the sacrifice layers 110A are removed via the trench STA to form a plurality of spaces 110B. As a result, a hollow structure including the plurality of insulating layers 101 and the insulating layer 102 arranged in the Z-direction and a structure inside the memory hole MH supporting these insulating layers (the semiconductor column 120, the gate insulating film 130, the semiconductor member 126, and the insulating layer 127) is formed. This process is performed by the method, such as wet etching.

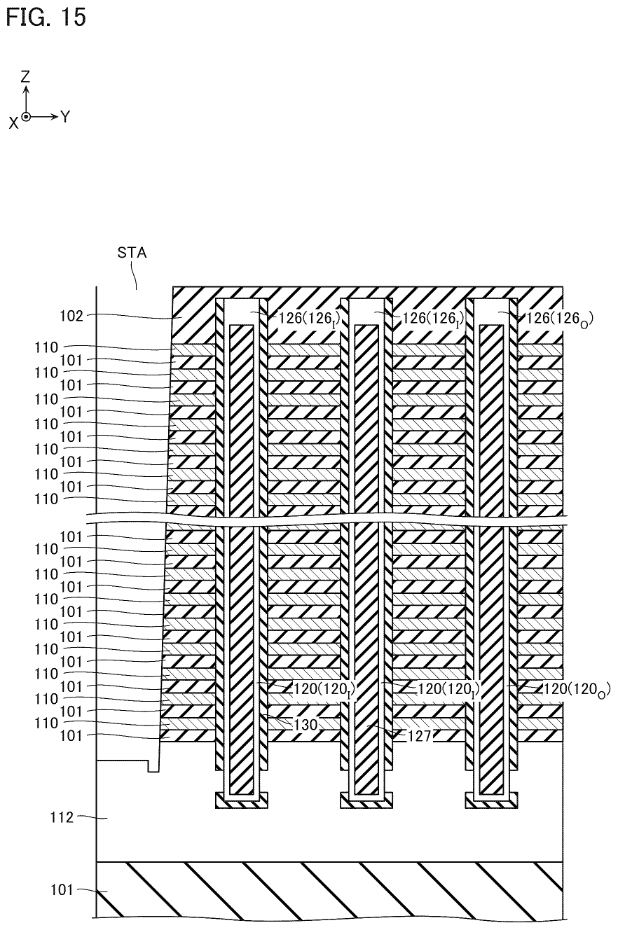

Next, for example, as illustrated in FIG. 15, the conductive layers 110 are formed in the spaces 110B. This process is performed by the method, such as CVD.

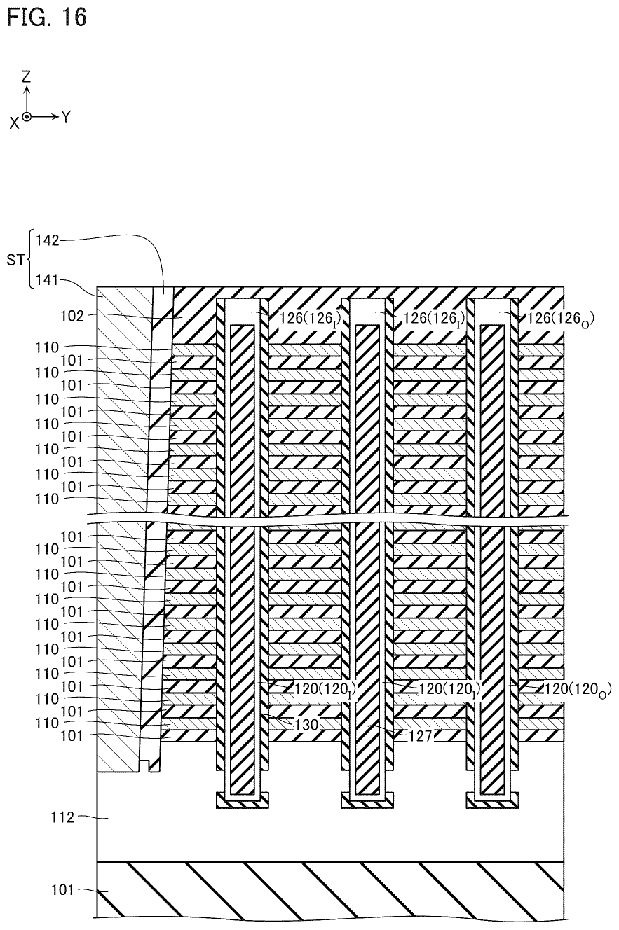

Next, for example, as illustrated in FIG. 16, the inter-finger structure ST is formed in the trench STA. This process is performed by the method, such as CVD and RIE.

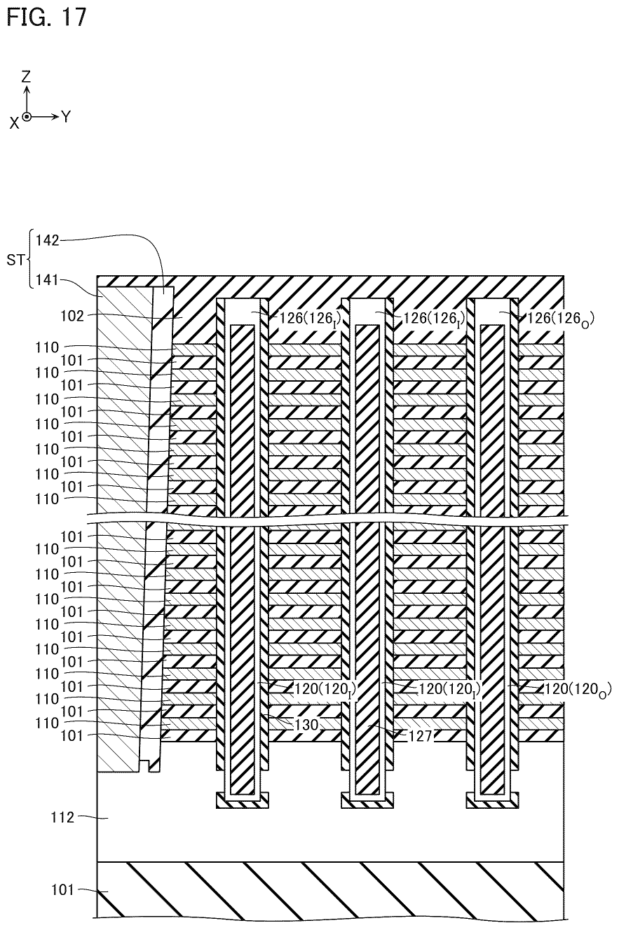

Next, for example, as illustrated in FIG. 17, a part of the insulating layer 102 is formed by the method, such as CVD.

Next, for example, as illustrated in FIG. 18 and FIG. 19, a trench SHEA is formed at a position corresponding to the insulating member SHE. The trench SHEA extends in the Z-direction and the X-direction, and separates the insulating layer 102, the conductive layer 110 (SGDT) and the conductive layers 110 (SGD), and the insulating layers 101 disposed therebetween in the Y-direction. This process is performed by the method, such as RIE.

In this process, the semiconductor column 120_{O} is partially removed. As a result, the regions 124, 125 (FIG. 4) of the semiconductor column 120_{O} are formed in the arc shape when viewed in the Z-direction as described with reference to FIG. 3 in some cases.

In this process, the semiconductor member 1260 is partially removed. Here, in the example of FIG. 18 and FIG. 19, the removal of the semiconductor member 1260 progresses faster than the removal of the insulating layers 102, 127. Therefore, the recessed portion 126A is formed at a surface exposed to the trench SHEA of the semiconductor member 126. As a result, the semiconductor member 1260 is formed in a columnar shape with a missing part when viewed in the Z-direction as described with reference to FIG. 8 in some cases.

Next, for example, as illustrated in FIG. 20 and FIG. 21, an insulating layer SHEB is formed on the upper surface of the insulating layer 102 and inside the trench SHEA. This process is performed by the method, such as CVD.

In this process, the insulating layer SHEB is formed on the inner surface in the Y-direction and a bottom surface of the trench SHEA and the upper surface of the insulating layer 102. Inside the trench SHEA, the insulating layer SHEB grows mainly from the inner surface of the trench SHEA in the Y-direction.

Here, in a region below the lower surface of the semiconductor member 126 (upper end of the insulating layer 127) of the trench SHEA, the inner surface in the Y-direction is approximately linearly formed. Therefore, the region below a predetermined height position of the trench SHEA is gaplessly filled mainly with the insulating layer SHEB growing from the inner surface of the trench SHEA in the Y-direction. Accordingly, in the region below the predetermined height position of the trench SHEA, a cavity or the like is not formed.

On the other hand, in a height region corresponding to the semiconductor member 126 of the trench SHEA, the inner surface on one side in the Y-direction is achieved by the recessed portion 126A. Therefore, at the height position corresponding to the semiconductor member 126 and the region at its proximity of the trench SHEA, the insulating layer SHEB grows from the recessed portion 126A. As a result, in the trench SHEA, at the height position corresponding to the semiconductor member 126 and its proximity, a plurality of cavities V1A (FIG. 20, FIG. 21) corresponding to the semiconductor column row SC1 and a plurality of cavities V2A (FIG. 20) corresponding to the semiconductor column row SC2 are formed.

The lengths in the Y-direction of the cavities V1A, V2A become maximum at a height position in the Z-direction corresponding to the most recessed part of the recessed portion 126A. The lengths in the Y-direction of the cavities V1A, V2A decrease as they get away from this height position. For example, the lengths in the Y-direction of the cavities V1A, V2A gradually decrease upward from this height position. The lengths in the Y-direction of the cavities V1A, V2A gradually decrease downward from this height position.

The lengths in the Y-direction of the cavities V1A, V2A become maximum at a position in the X-direction corresponding to the most recessed part of the recessed portion 126A. This position in the X-direction corresponds to, for example, a center position in the X-direction of the semiconductor member 126. The lengths in the Y-direction of the cavities V1A, V2A decrease as they get away from this position in the X-direction.

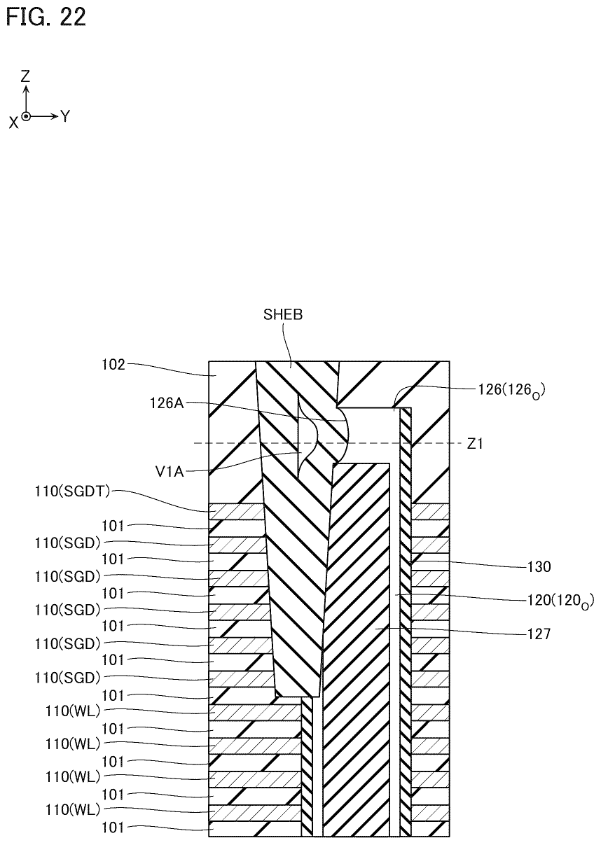

Next, for example, as illustrated in FIG. 22, a part of the insulating layer SHEB is removed. In this process, in the insulating layer SHEB, a portion formed on the upper surface of the insulating layer 102 is removed. In the example of the drawing, the cavity V1A has an upper end located below the upper surface of the insulating layer 102, and the cavity V1A is not communicated with the outside. This process is performed by the method, such as RIE. This process may be omitted.

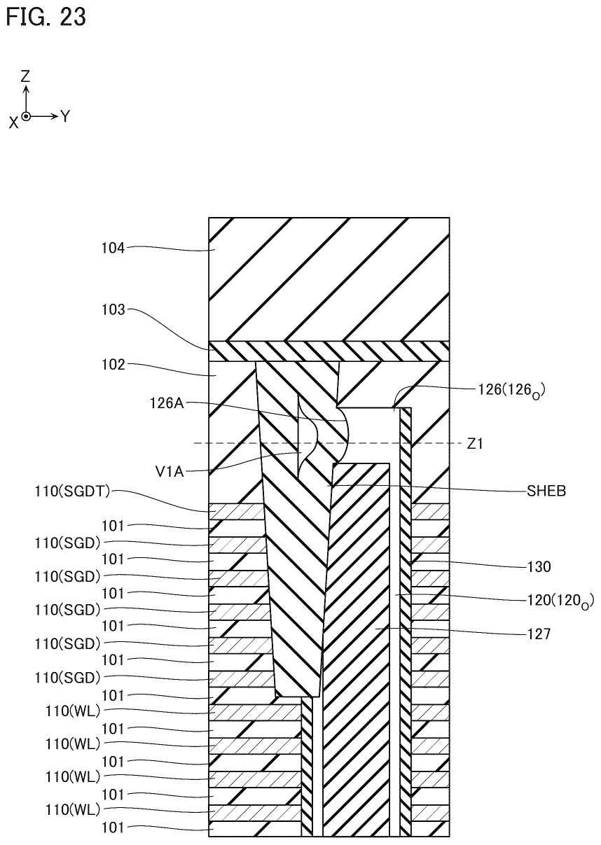

Next, for example, as illustrated in FIG. 23, the insulating layers 103, 104 are formed by the method, such as CVD.

Next, for example, as illustrated in FIG. 24 and FIG. 25, a contact hole ChA is formed at a position corresponding to the contact electrode Ch. The contact hole ChA extends in the Z-direction, and penetrates the insulating layers 102, 103, 104 and a part of the insulating layer SHEB to expose a part of the upper surface of the semiconductor member 126 and a part of the recessed portion 126A. This process is performed by the method, such as RIE.

In the example of FIG. 24 and FIG. 25, a plurality of the contact holes ChA are communicated with a plurality of the cavities V1A.

Next, for example, as illustrated in FIG. 26 and FIG. 27, the insulating layer of silicon oxide or the like is removed by the method, such as wet etching. In this process, the residue generated in the formation of the contact hole ChA in the process described with reference to FIG. 24 and FIG. 25 is removed, and a surface of the semiconductor member 126 is cleaned. This process may be omitted.

In the example of FIG. 26 and FIG. 27, a part of the insulating layer SHEB is removed, and the cavity V1A expands to a region corresponding to the region R3 described with reference to FIG. 6 and the like. That is, the insulating member SHE is formed. In the example of FIG. 26, a plurality of the contact holes ChA are communicated with a plurality of the cavities V2A, and a part of the cavities V1A are communicated with the cavities V2A. Therefore, a path from one contact hole ChA to another contact hole ChA via the cavities V1A, V2A is formed. In the example of FIG. 26 and FIG. 27, a part of the cavities V1A and a part of the cavities V2A arranged in the X-direction are mutually spaced in the Y-direction via the insulating member SHE. However, also in such a part, a path from one contact hole ChA to another contact hole ChA via the cavities V1A, V2A is formed due to a seam extending in the Y-direction in the insulating member SHE in some cases.

In the example of FIG. 26 and FIG. 27, a part of the insulating layer SHEB is etched and isotropically removed. Therefore, the lengths in the Y-direction of the cavities V1A, V2A become maximum at a height position in the Z-direction corresponding to the most recessed part of the recessed portion 126A. The lengths in the Y-direction of the cavities V1A, V2A decrease as they get away from this height position. Similarly, the lengths in the Y-direction of the cavities V1A, V2A become maximum at a position in the X-direction corresponding to the most recessed part of the recessed portion 126A. The lengths in the Y-direction of the cavities V1A, V2A decrease as they get away from this position in the X-direction.

Here, when focusing on those communicated with the cavities V2A among the plurality of cavities V1A, these cavities V1A have end portions in the X-direction connected to end portions of the cavities V2A in the X-direction. Since the lengths in the Y-direction of the cavities V1A, V2A decrease as they get away from the position in the X-direction corresponding to the most recessed part of the recessed portion 126A, a length in the Y-direction of a connecting portion between the cavities V1A, V2A is relatively small. The length in the Y-direction of the connecting portion between the cavities V1A, V2A is at least smaller than the maximum length in the Y-direction of the cavity V1A and the maximum length in the Y-direction of the cavity V2A.

Next, for example, as illustrated in FIG. 28 and FIG. 29, the insulating member 151A is formed inside the contact hole ChA and the cavities V1A, V2A. This process is performed by the method, such as CVD.

Here, as described with reference to FIG. 26, the length in the Y-direction of the connecting portion between the cavities V1A, V2A is relatively small. Therefore, when the formation of the insulating member 151A starts, the connecting portion between the cavities V1A, V2A is gaplessly filled with the insulating member 151A and closed at a relatively early stage, and the cavity V1A is separated from the cavity V2A. Thus, the plurality of cavities V1 are separated from any of the plurality of cavities V2.

As described with reference to FIG. 27, the lengths in the Y-direction of the cavities V1A, V2A decrease as they get away from the height position in the Z-direction corresponding to the most recessed part of the recessed portion 126A. Therefore, when the formation of the insulating member 151A starts, relatively lower portions of the cavities V1A, V2A are gaplessly filled with the insulating member 151A at a relatively early stage.

When the path from the contact hole ChA to the cavity V1A is closed before the cavity V1A is completely filled with the insulating member 151A, as illustrated in the drawing, the cavity V1 is formed inside the cavity V1A. Similarly, when the path from the contact hole ChA to the cavity V2A is closed before the cavity V2A is completely filled with the insulating member 151A, as illustrated in the drawing, the cavity V2 is formed inside the cavity V2A.

In the example of FIG. 28 and FIG. 29, approximately the whole regions (regions excluding the cavities V1, V2) in the cavities V1A, V2A are filled with the insulating member 151A. Further, a region of the contact hole ChA provided below the upper surface of the semiconductor member 126 (hereinafter referred to as a “lower region”) is filled with the insulating member 151A. On the other hand, a region of the contact hole ChA provided above the upper surface of the semiconductor member 126 (hereinafter referred to as an “upper region”) is not filled with the insulating member 151A.

Next, for example, as illustrated in FIG. 30, a part of the insulating member 151A is removed to expose the semiconductor member 126 to the inside of the contact hole ChA. In this process, the insulating member 151A is partially removed by the method, such as RIE. With the use of diluted hydrofluoric acid (DHF) or the like, the residue generated in the removal of a part of the insulating member 151A is removed and the surface of the semiconductor member 126 is cleaned.

In the example of FIG. 30, a portion formed on an upper surface of the insulating layer 104 of the insulating member 151A is removed. A portion provided on an inner peripheral surface of the contact hole ChA of the insulating member 151A remains and is provided as the insulating film 157.

In this embodiment, a portion provided in the cavity V1A of the insulating member 151A is provided as the insulating portion 153 (FIG. 8) of the insulating member 151. The portion provided in the cavity V2A of the insulating member 151A is provided as the insulating portion 155 (FIG. 8) of the insulating member 152. A portion provided in the lower region of the contact hole ChA of the insulating member 151A is provided as the insulating portion 154 (FIG. 8) of the insulating member 151 or the insulating portion 156 (FIG. 8) of the insulating member 152.

Then, the contact electrode Ch is formed inside the contact hole ChA by the method, such as CVD, thus forming the structure described with reference to FIG. 6 and FIG. 7. At this time, the portion formed in the upper region of the contact hole ChA is provided as the conductive region R_{Ch1} described with reference to FIG. 6 and the like, and the portion formed in the lower region of the contact hole ChA is provided as the conductive region R_{Ch2} described with reference to FIG. 6 and the like. By forming the contact electrode Vy and the bit line BL, the structure described with reference to FIG. 4 is formed.

### [Effects of First Embodiment]

In the example described with reference to FIG. 20 and FIG. 21, inside the insulating layer SHEB, a plurality of the cavities V1A corresponding to the semiconductor members 126 in the semiconductor column row SC1 and a plurality of the cavities V2A corresponding to the semiconductor members 126 in the semiconductor column row SC2 are formed. These cavities V1A, V2A are communicated with the contact holes ChA in the process described with reference to FIG. 24 to FIG. 27. Further, as exemplified in FIG. 26, the cavity V1A is communicated with the cavity V2A in some cases.

Here, for example, when the contact electrode Ch is formed in the contact hole ChA immediately after the process described with reference to FIG. 26 and FIG. 27, a plurality of the contact electrodes Ch possibly short-circuit via the cavities V1A, V2A. Even when the cavity V1A is not directly connected to the cavity V2A, it is not preferred in terms of withstand voltage that the contact electrodes Ch are formed to be mutually adjacent in the respective cavities V1A, V2A communicated via the seam.

From the aspect of withstand voltage, it is preferred to ensure a certain distance or more between the contact electrode Ch and the drain-side select gate line SGDT. Especially, when the lower ends of the cavities V1A, V2A are provided below the upper surface of the uppermost conductive layer 110, the contact electrode Ch becomes close to the uppermost conductive layer 110.

Therefore, in the manufacture of the semiconductor memory device according to the first embodiment, as described with reference to FIG. 28 to FIG. 30, the insulating members 151, 152 are formed inside the cavities V1A, V2A.

Here, as described above, the length in the Y-direction of the connecting portion between the cavities V1A, V2A is relatively small. Accordingly, with such a method, the connecting portion between the cavities V1A, V2A is filled with the insulating member 151A and closed to separate the cavity V1A from the cavity V2A, thereby enabling reducing the occurrence of the short circuit between the contact electrodes Ch. Similarly, even when the cavities V1A, V2A are not connected to one another, the path extending in the Y-direction between the cavities V1A, V2A via the seam is closed by the insulating member 151A, thereby enabling the improvement of the withstand voltage between the contact electrodes Ch.

The lengths in the Y-direction of the cavities V1A, V2A decrease as they get away from the height position in the Z-direction corresponding to the most recessed part of the recessed portion 126A. Therefore, with such a method, the relatively lower portions of the cavities V1A, V2A (for example, portions formed by expanding the cavities V1A, V2A in the Y-direction and provided below the height position corresponding to the semiconductor member 126 and the region at the proximity of the height position) are filled with the insulating member 151A to restrain the distance between the lower end of the contact electrode Ch and the conductive layer 110 from decreasing to a certain distance or less, thereby enabling ensuring the certain distance or more between the contact electrode Ch and the drain-side select gate line SGDT.

Especially, in this embodiment, the cavities V1, V2 are spaced from the contact electrodes Ch via a part of the insulating portions 153, 155. With this configuration, since the conductive member constituting the contact electrode Ch is not formed inside the cavities V1, V2, the withstand voltage between the contact electrodes Ch can be appropriately ensured, and the withstand voltage between the contact electrode Ch and the drain-side select gate line SGDT also can be more appropriately ensured.

### Second Embodiment

In the first embodiment, in the process described with reference to FIG. 30, a part of the insulating member 151A (FIG. 29) remains in the lower region of the contact hole ChA, and is provided as the insulating portion 154 (FIG. 8) of the insulating member 151 or the insulating portion 156 (FIG. 8) of the insulating member 152. However, such a configuration is merely an example, and a part of the insulating member 151A (FIG. 29) does not need to remain in the lower region of the contact hole ChA. Such an example is described as the second embodiment.

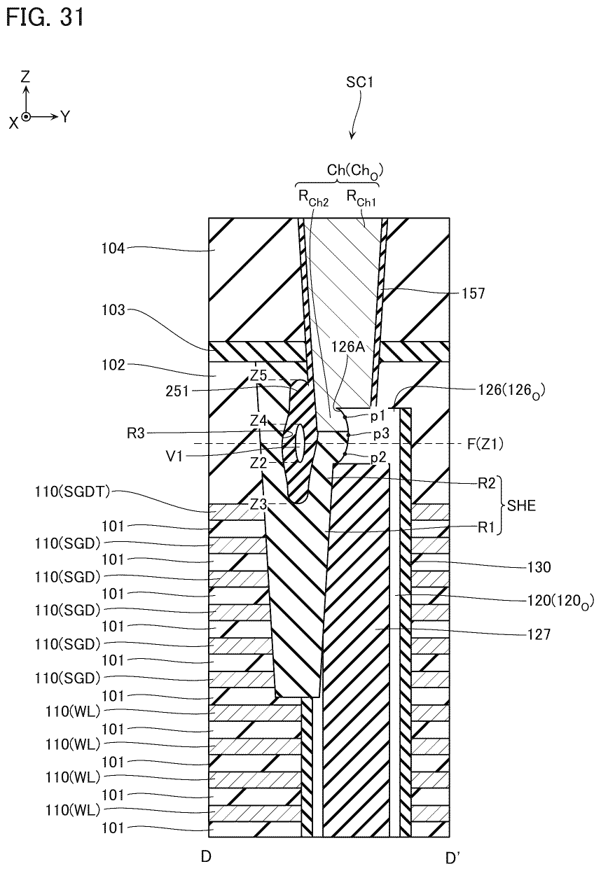

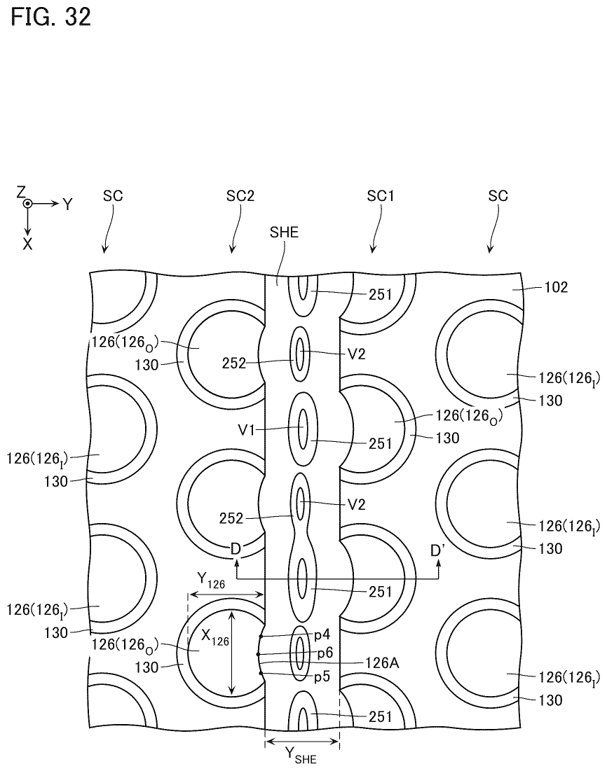

FIG. 31 is a schematic cross-sectional view illustrating a part of a configuration of a semiconductor memory device according to the second embodiment. FIG. 32 is a schematic XY cross-sectional view illustrating a part of the configuration of the semiconductor memory device. FIG. 31 is a schematic cross-sectional view of the structure illustrated in FIG. 32 taken along the line D-D′ and viewed along an arrow direction. FIG. 32 illustrates an XY cross-sectional surface at a height position corresponding to a dashed line F indicated in FIG. 31. In the following description, the same reference numerals are attached to parts similar to those in the first embodiment, and the explanation will be omitted.

The semiconductor memory device according to the second embodiment is basically configured similarly to the semiconductor memory device according to the first embodiment. However, in the second embodiment, the lower surface of the conductive region R_{Ch2} of the contact electrode Ch_{O} is in contact with the insulating member SHE. Further, the semiconductor memory device according to the second embodiment includes insulating members 251, 252 instead of the insulating members 151, 152.

The insulating member 251 is basically configured similarly to the insulating member 151. However, the insulating member 251 is configured similarly to the insulating portion 153, and does not have a portion corresponding to the insulating portion 154. The insulating member 251 is surrounded by the insulating member SHE and the contact electrode Ch.

A length in the Y-direction of the insulating member 251 becomes maximum at a height position in the Z-direction corresponding to the most recessed part of the recessed portion 126A. The length in the Y-direction of the insulating member 251 decreases as it gets away from this height position. For example, the length in the Y-direction of the insulating member 251 gradually decreases upward from this height position. For example, the length in the Y-direction of the insulating member 251 at the height position Z4 is smaller than the length in the Y-direction of the insulating member 251 at the height position Z1. The length in the Y-direction of the insulating member 251 gradually decreases downward from this height position. For example, the length in the Y-direction of the insulating member 251 at the height position Z2 is smaller than the length in the Y-direction of the insulating member 251 at the height position Z1.

As illustrated in FIG. 32, the insulating member 251 expands in the Y-direction along the recessed portion 126A when viewed in the Z-direction.

The insulating member 252 is basically configured similarly to the insulating member 152. However, the insulating member 252 is configured similarly to the insulating portion 155, and does not have a portion corresponding to the insulating portion 156. The insulating member 252 is surrounded by the insulating member SHE and the contact electrode Ch.

Although not illustrated, a length in the Y-direction of the insulating member 252 becomes maximum at a height position in the Z-direction corresponding to the most recessed part of the recessed portion 126A. The length in the Y-direction of the insulating member 252 decreases as it gets away from this height position. For example, the length in the Y-direction of the insulating member 252 gradually decreases upward from this height position. For example, the length in the Y-direction of the insulating member 252 at the height position Z14 (see FIG. 7) is smaller than the length in the Y-direction of the insulating member 252 at the height position Z1 (see FIG. 7). The length in the Y-direction of the insulating member 252 gradually decreases downward from this height position. For example, the length in the Y-direction of the insulating member 252 at the height position Z12 (see FIG. 7) is smaller than the length in the Y-direction of the insulating member 252 at the height position Z1 (see FIG. 7).

As illustrated in FIG. 32, the insulating member 252 expands in the Y-direction along the recessed portion 126A when viewed in the Z-direction.

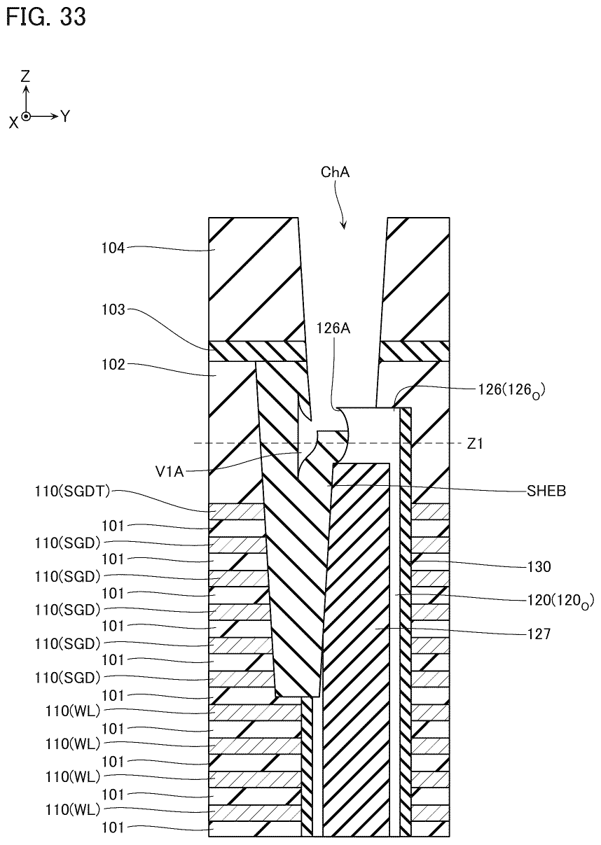

Next, with reference to FIG. 33 to FIG. 36, a method for manufacturing the semiconductor memory device according to the second embodiment is described. FIG. 33 to FIG. 36 are schematic cross-sectional views for describing the manufacturing method. FIG. 33 to FIG. 36 illustrate the cross-sectional surface corresponding to FIG. 31.

In the manufacture of the semiconductor memory device according to the second embodiment, the method for manufacturing the semiconductor memory device according to the first embodiment is performed up to the process described with reference to FIG. 23.

Next, as illustrated in FIG. 33, a contact hole ChA is formed at a position corresponding to the contact electrode Ch. This process is basically performed similarly to the process described with reference to FIG. 24 and FIG. 25.

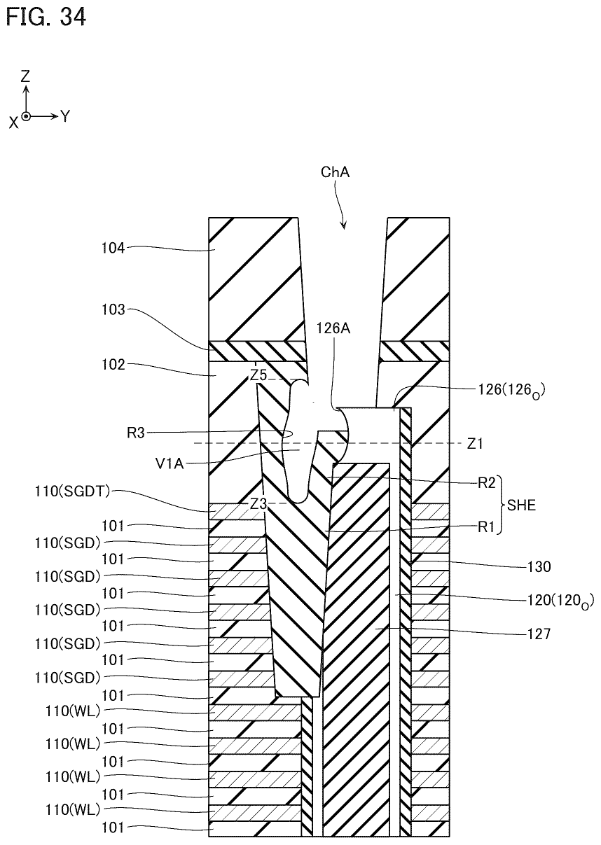

Next, as illustrated in FIG. 34, the insulating layer of silicon oxide or the like is removed by the method, such as wet etching. This process is performed similarly to the process described with reference to FIG. 26 and FIG. 27.

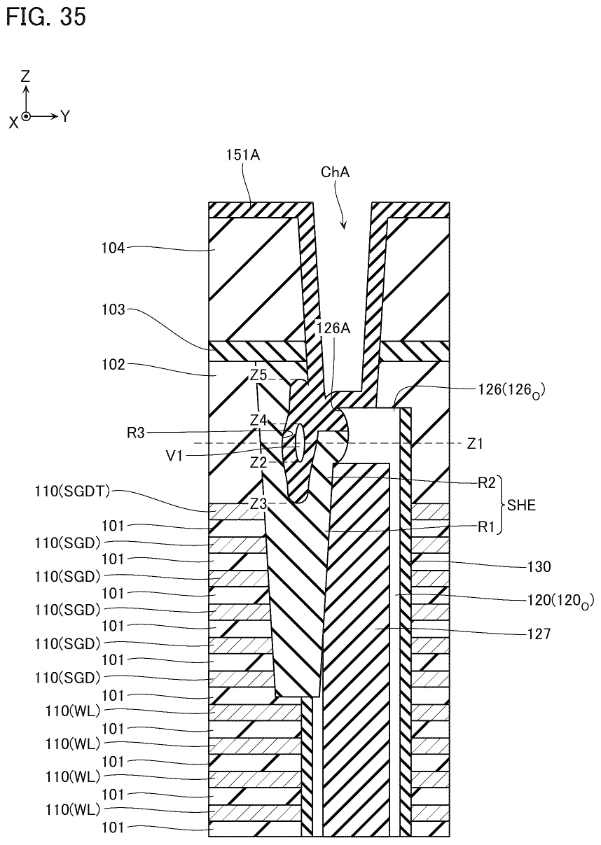

Next, as illustrated in FIG. 35, the insulating member 151A is formed inside the contact hole ChA and the cavities V1A, V2A. This process is performed similarly to the process described with reference to FIG. 28 and FIG. 29.

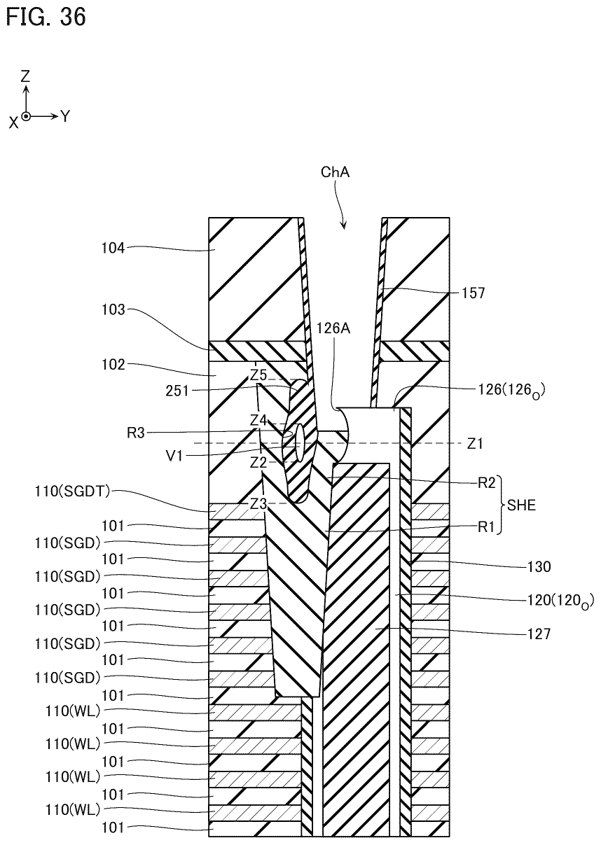

Next, for example, as illustrated in FIG. 36, a part of the insulating member 151A is removed to expose the semiconductor member 126 to the inside of the contact hole ChA. This process is basically performed similarly to the process described with reference to FIG. 30.

However, in this embodiment, the portion provided in the lower region of the contact hole ChA (FIG. 26) of the insulating member 151A is removed, and the insulating member SHE is exposed from the bottom surface of the contact hole ChA. Thus, the insulating members 251, 252 are formed.

Then, the processes after the formation of the contact electrode Ch in the method for manufacturing the semiconductor memory device according to the first embodiment are performed.

The semiconductor memory device according to the second embodiment can provide the effect similar to that of the semiconductor memory device according to the first embodiment as well.

### Third Embodiment

In the second embodiment, in the process described with reference to FIG. 36, a part of the insulating member 151A remains on the inner peripheral surface of the contact hole ChA, and is provided as the insulating film 157. However, such a configuration is merely an example, and a part of the insulating member 151A (FIG. 35) does not need to remain on the inner peripheral surface of the contact hole ChA. Such an example is described as the third embodiment.

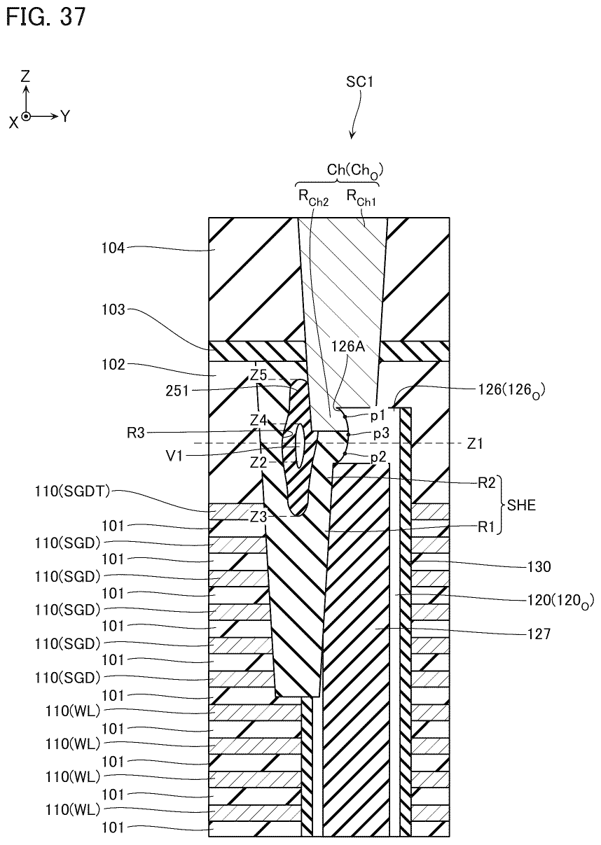

FIG. 37 is a schematic cross-sectional view illustrating a part of a configuration of a semiconductor memory device according to the third embodiment. In the following description, the same reference numerals are attached to parts similar to those in the second embodiment, and the explanation will be omitted.

The semiconductor memory device according to the third embodiment is basically configured similarly to the semiconductor memory device according to the second embodiment. However, the semiconductor memory device according to third embodiment does not include the insulating film 157.

The semiconductor memory device according to the third embodiment is basically manufactured similarly to the semiconductor memory device according to the second embodiment. However, in the manufacture of the semiconductor memory device according to the third embodiment, in the process corresponding to FIG. 36, the portion provided on the inner peripheral surface of the contact hole ChA of the insulating member 151A is removed.

The semiconductor memory device according to the third embodiment can provide the effect similar to that of the semiconductor memory device according to the second embodiment as well.

Similarly to the semiconductor memory device according to third embodiment, the semiconductor memory device according to the first embodiment does not need to include the insulating film 157.

### Fourth Embodiment

In the third embodiment, in the process corresponding to FIG. 36, the cavity V1 is not communicated with the contact hole ChA. However, in the process corresponding to FIG. 36, the cavity V1 may be communicated with the contact hole ChA. Such an example is described as the fourth embodiment.

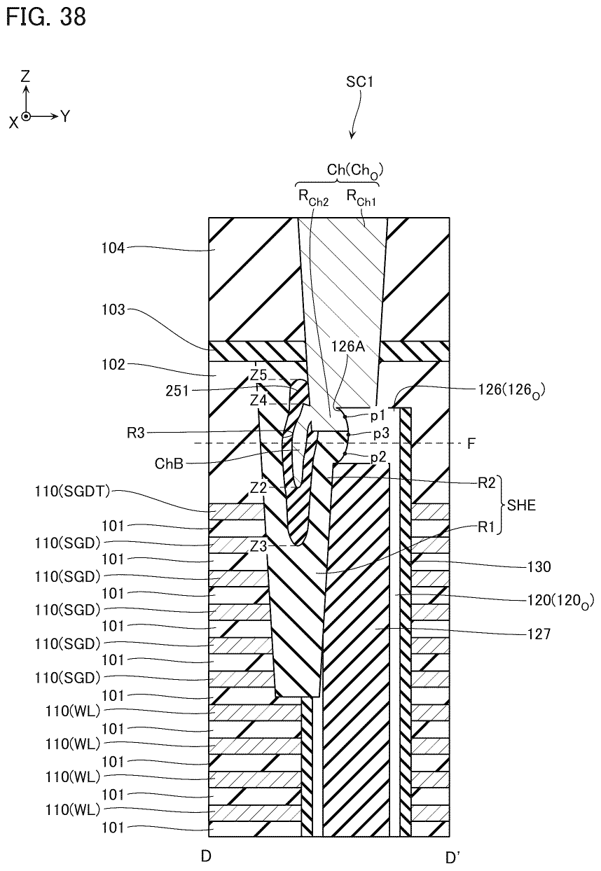

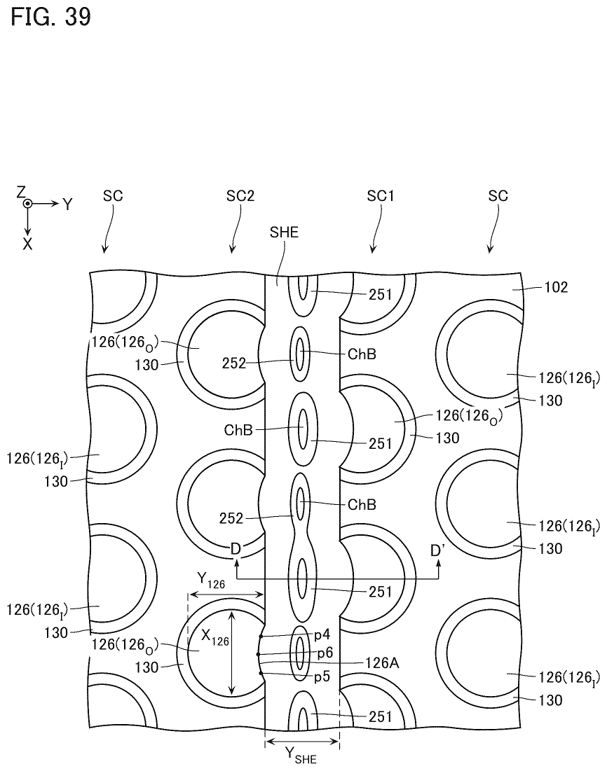

FIG. 38 is a schematic cross-sectional view illustrating a part of a configuration of a semiconductor memory device according to the fourth embodiment. FIG. 39 is a schematic XY cross-sectional view illustrating a part of the configuration of the semiconductor memory device. FIG. 38 is a schematic cross-sectional view of the structure illustrated in FIG. 39 taken along the line D-D′ and viewed along an arrow direction. FIG. 39 illustrates an XY cross-sectional surface at a height position corresponding to a dashed line F indicated in FIG. 38. In the following description, the same reference numerals are attached to parts similar to those in the third embodiment, and the explanation will be omitted.

The semiconductor memory device according to the fourth embodiment is basically configured similarly to the semiconductor memory device according to the third embodiment. However, the semiconductor memory device according to the fourth embodiment includes conductive members ChB instead of the cavities V1, V2. That is, the conductive members ChB are filled in the cavities V1, V2.

The conductive members ChB contains a material similar to that of the contact electrode Ch. For example, the conductive members ChB may include, for example, a stacked film of a barrier conductive film of titanium nitride (TiN) or the like and a metal film of tungsten (W) or the like. The conductive members ChB are disposed inside the insulating members 251, 252, and each continuous with the corresponding contact electrode Ch. For example, the barrier conductive films in the conductive members ChB are continuous with the barrier conductive films in the contact electrodes Ch. Similarly, the metal films in the conductive members ChB are continuous with the metal films in the contact electrodes Ch.

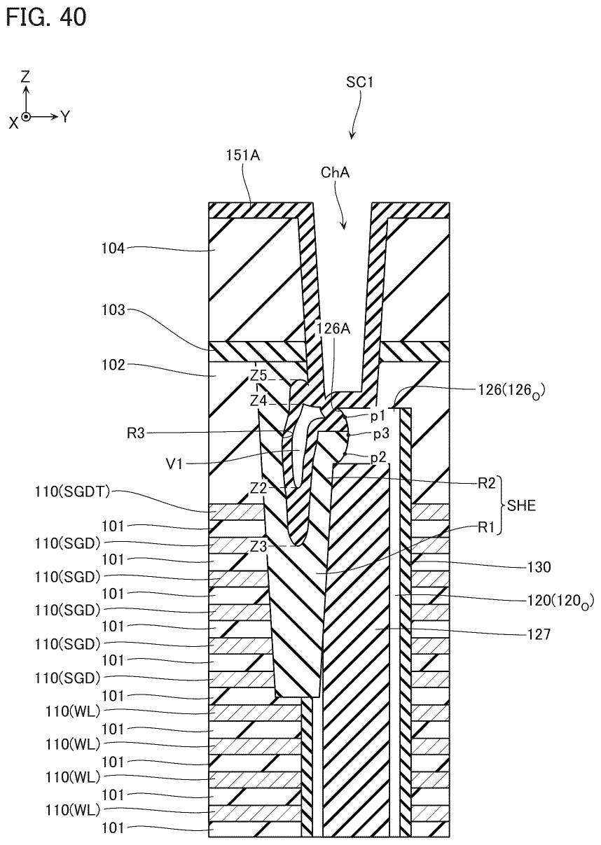

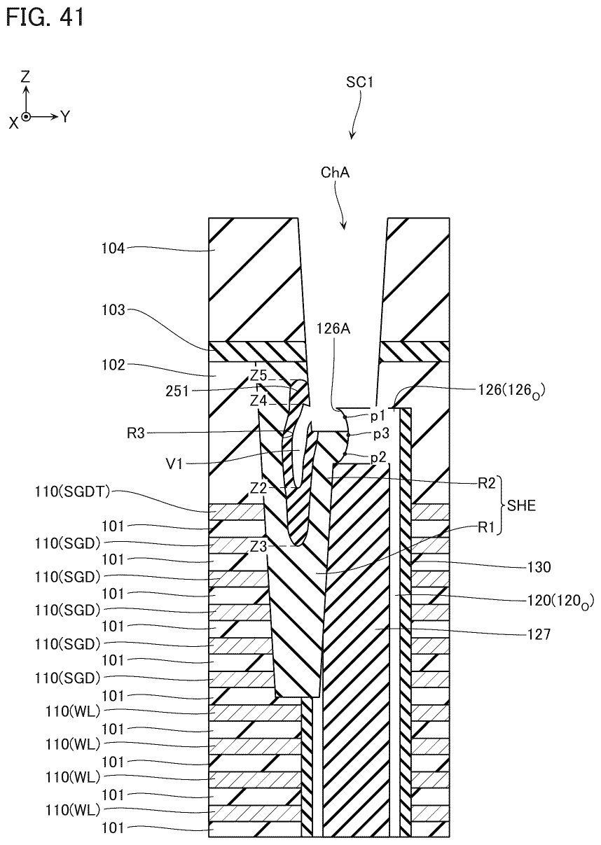

Next, with reference to FIG. 40 and FIG. 41, a method for manufacturing the semiconductor memory device according to the fourth embodiment is described. FIG. 40 and FIG. 41 are schematic cross-sectional views for describing the manufacturing method. FIG. 40 and FIG. 41 illustrate the cross-sectional surface corresponding to FIG. 38.

The semiconductor memory device according to the fourth embodiment is basically manufactured similarly to the semiconductor memory device according to the third embodiment. However, in the manufacture of the semiconductor memory device according to the fourth embodiment, in the process corresponding to FIG. 35, as illustrated in FIG. 40, the cavity V1 expands to the proximity of the contact hole ChA. Further, in the process corresponding to FIG. 36, as illustrated in FIG. 41, the portion disposed on the inner peripheral surface of the contact hole ChA of the insulating member 151A is removed, and the cavity V1 is communicated with the contact hole ChA. In the formation of the contact electrode Ch, a metal or the like constituting the contact electrode Ch enters into the cavities V1, V2.

In the fourth embodiment, in the process described with reference to FIG. 41, the cavity V1 is communicated with the contact hole ChA. Therefore, in the formation of the contact electrode Ch, a metal or the like constituting the contact electrode Ch enters into the cavities V1, V2. However, as described with reference to FIG. 28, by filling at least a part of the path between the two contact holes ChA communicated via the cavities V1A, V2A with the insulating member 151A to close the path and separating the two contact holes ChA from one another, even when a metal or the like constituting the contact electrode Ch enters into the cavities V1, V2, the occurrence of the short circuit between the contact electrodes Ch can be suppressed. The relatively lower portions of the cavities V1A, V2A (for example, portions formed by expanding the cavities V1A, V2A in the Y-direction and provided below the height position corresponding to the semiconductor member 126 and the region at the proximity of the height position) are filled with the insulating member 151A, thereby enabling ensuring the distance between the contact electrode Ch and the drain-side select gate line SGDT compared with a case where the insulating member 151A is not formed.

Similarly to the semiconductor memory device according to the fourth embodiment, the semiconductor memory devices according to the first embodiment and the second embodiment may include the conductive members ChB instead of the cavities V1, V2.

### Fifth Embodiment

In the first embodiment, the insulating members 151, 152 are internally provided with the cavities V1, V2, respectively. However, the insulating members 151, 152 do not need to be internally provided with the cavities V1, V2. Such an example is described as the fifth embodiment.

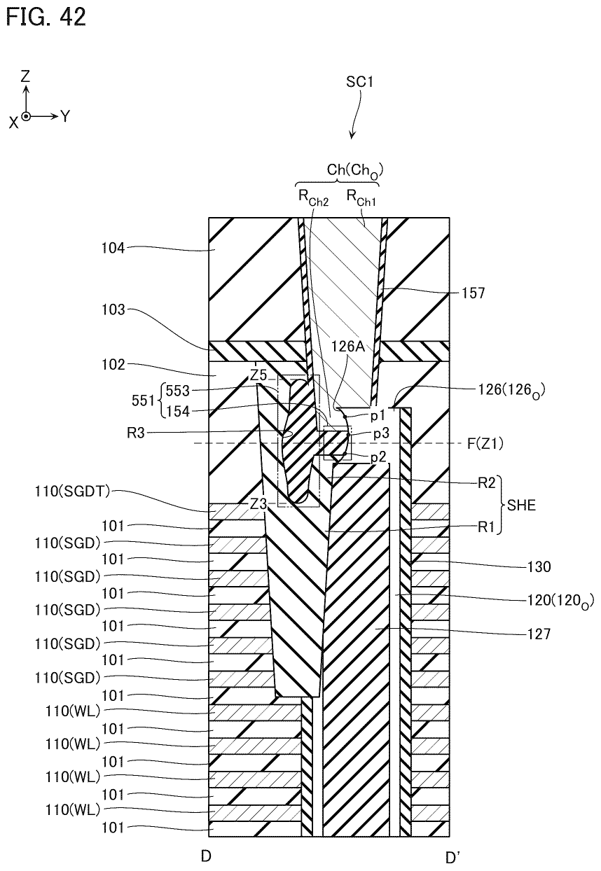

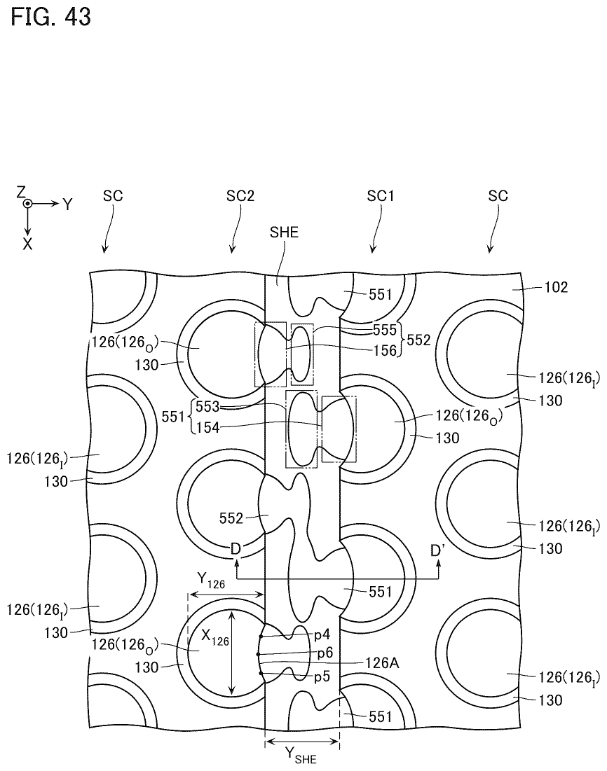

FIG. 42 is a schematic cross-sectional view illustrating a part of a configuration of a semiconductor memory device according to the fifth embodiment. FIG. 43 is a schematic XY cross-sectional view illustrating a part of the configuration of the semiconductor memory device. FIG. 42 is a schematic cross-sectional view of the structure illustrated in FIG. 43 taken along the line D-D′ and viewed along an arrow direction. FIG. 43 illustrates an XY cross-sectional surface at a height position corresponding to a dashed line F indicated in FIG. 42. In the following description, the same reference numerals are attached to parts similar to those in the first embodiment, and the explanation will be omitted.

The semiconductor memory device according to the fifth embodiment is basically configured similarly to the semiconductor memory device according to the first embodiment. However, the semiconductor memory device according to the fifth embodiment includes insulating members 551, 552 instead of the insulating members 151, 152.

The insulating member 551 is basically configured similarly to the insulating member 151. However, the insulating member 551 includes an insulating portion 553 instead of the insulating portion 153. The insulating portion 553 is basically configured similarly to the insulating portion 153. Here, the insulating portion 553 is not internally provided with the cavity V1.

The insulating member 552 is basically configured similarly to the insulating member 152. However, the insulating member 552 includes an insulating portion 555 instead of the insulating portion 155. The insulating portion 555 is basically configured similarly to the insulating portion 155. Here, the insulating portion 555 is not internally provided with the cavity V2.

The semiconductor memory device according to the fifth embodiment is basically manufactured similarly to the semiconductor memory device according to the first embodiment. However, in the manufacture of the semiconductor memory device according to the fifth embodiment, in the process described with reference to FIG. 28 and FIG. 29, insides of the cavities V1A, V2A are completely filled with the insulating member 151A, and the cavities V1, V2 are not formed inside the insulating members 551, 552.

The semiconductor memory device according to the fifth embodiment can provide the effect similar to that of the semiconductor memory device according to the first embodiment as well.

Similarly to the insulating members 551, 552 according to the fifth embodiment, the insulating members 251, 252 according to the second embodiment and the third embodiment do not need to be internally provided with the cavities V1, V2.

### Sixth Embodiment

As described above, the semiconductor memory device according to the first embodiment does not need to include the insulating film 157 similarly to the semiconductor memory device according to the third embodiment. Further, as exemplified as the fifth embodiment, in the semiconductor memory device according to the first embodiment, the insulating members 151, 152 do not need to be internally provided with the cavities V1, V2. Such an example is described as the sixth embodiment.

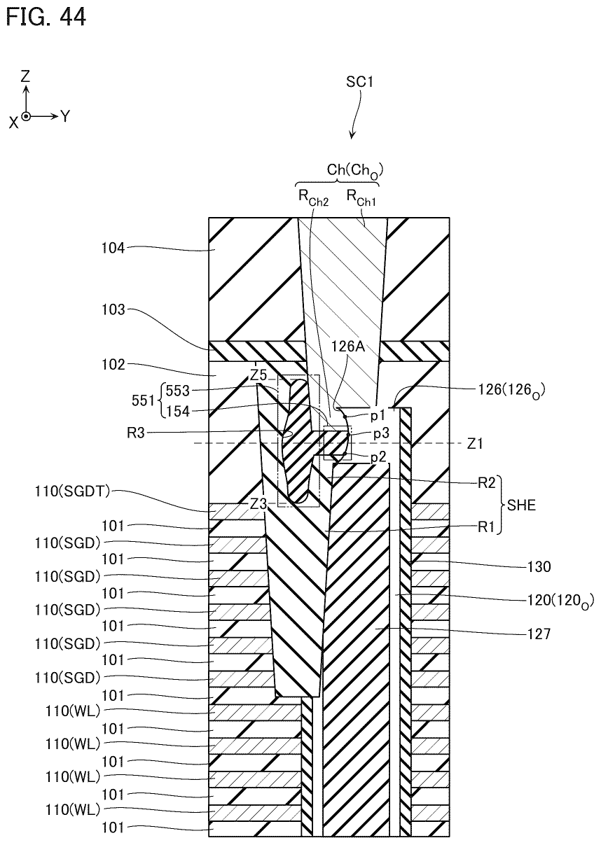

FIG. 44 is a schematic cross-sectional view illustrating a part of a configuration of a semiconductor memory device according to the sixth embodiment. In the following description, the same reference numerals are attached to parts similar to those in the fifth embodiment, and the explanation will be omitted.

The semiconductor memory device according to the sixth embodiment is basically configured similarly to the semiconductor memory device according to the fifth embodiment. However, the semiconductor memory device according to the sixth embodiment does not include the insulating film 157.

The semiconductor memory device according to the sixth embodiment is basically manufactured similarly to the semiconductor memory device according to the fifth embodiment. However, in the manufacture of the semiconductor memory device according to the sixth embodiment, in the process corresponding to FIG. 30, the portion provided on the inner peripheral surface of the contact hole ChA of the insulating member 151A is removed.

The semiconductor memory device according to the sixth embodiment can provide the effect similar to that of the semiconductor memory device according to the first embodiment as well.

### Seventh Embodiment

In the first embodiment, the insulating members 151, 152 contain silicon oxide. However, the insulating members 151, 152 may be configured of a material containing silicon (Si), oxygen (O), and additionally another element, such as silicon oxynitride (SiON) and carbon-containing silicon oxide (SiOC). The insulating members 151, 152 may be configured of a material containing silicon and an element other than oxygen, such as silicon nitride (SiN). Especially, silicon oxynitride, carbon-containing silicon oxide, silicon nitride, and the like have high resistance against diluted hydrofluoric acid (DHF) compared with silicon oxide. Therefore, in the process described with reference to FIG. 30, excessive removal of the insulating member 151A can be suppressed.

The insulating members 151, 152 may contain a plurality of materials. For example, the insulating members 151, 152 may include an insulating region containing one of silicon oxide, silicon oxynitride, carbon-containing silicon oxide, silicon nitride, or another material and an insulating region containing another one thereof. Such an example is described as the seventh embodiment.

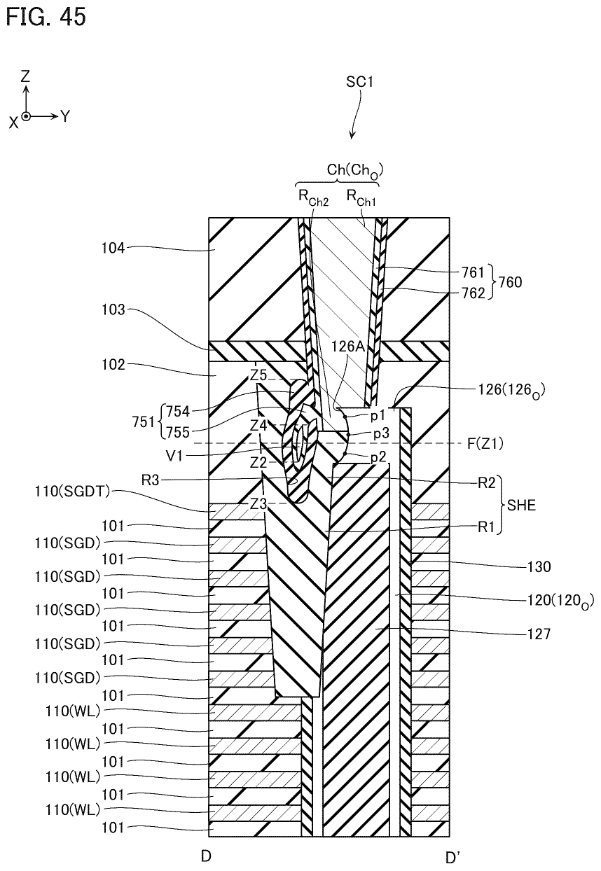

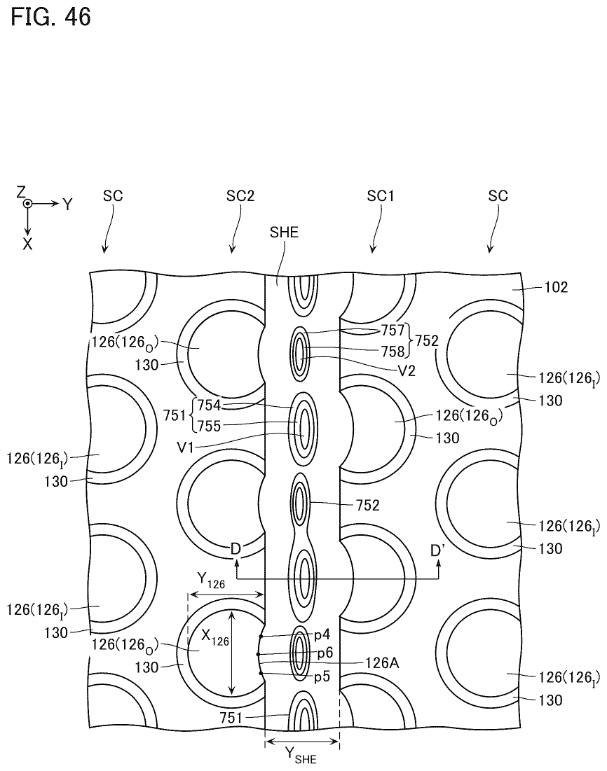

FIG. 45 is a schematic cross-sectional view illustrating a part of a configuration of a semiconductor memory device according to the seventh embodiment. FIG. 46 is a schematic XY cross-sectional view illustrating a part of the configuration of the semiconductor memory device. FIG. 45 is a schematic cross-sectional view of the structure illustrated in FIG. 46 taken along the line D-D′ and viewed along an arrow direction. FIG. 46 illustrates an XY cross-sectional surface at a height position corresponding to a dashed line F indicated in FIG. 45. In the following description, the same reference numerals are attached to parts similar to those in the second embodiment, and the explanation will be omitted.

The semiconductor memory device according to the seventh embodiment is basically configured similarly to the semiconductor memory device according to the second embodiment. However, the semiconductor memory device according to the seventh embodiment includes insulating members 751, 752 instead of the insulating members 251, 252. The semiconductor memory device according to the seventh embodiment includes an insulating film 760 instead of the insulating film 157.

The insulating member 751 includes an insulating region 754 and an insulating region 755 provided inside the insulating region 754. The insulating region 754 is configured approximately similarly to the insulating member 251. However, the insulating region 754 is not in contact with the contact electrode Ch. The insulating region 754 contains silicon oxide. The insulating region 755 is in contact with the contact electrode Ch. The insulating region 755 is internally provided with the cavity V1. The insulating region 755 contains a material, such as silicon oxynitride, carbon-containing silicon oxide, and silicon nitride, having high resistance against diluted hydrofluoric acid compared with silicon oxide.

The insulating member 752 includes an insulating region 757 and an insulating region 758 provided inside the insulating region 757. The insulating region 757 is configured approximately similarly to the insulating member 252. However, the insulating region 757 is not in contact with the contact electrode Ch. The insulating region 757 contains silicon oxide. The insulating region 758 is in contact with the contact electrode Ch. The insulating region 758 is internally provided with the cavity V2. The insulating region 758 contains a material, such as silicon oxynitride, carbon-containing silicon oxide, and silicon nitride, having high resistance against diluted hydrofluoric acid compared with silicon oxide.

The insulating film 760 is basically configured similarly to the insulating film 157. However, the insulating film 760 includes an insulating region 761 extending in the Z-direction along the outer peripheral surface of the contact electrode Ch, and an insulating region 762 extending in the Z-direction along an outer peripheral surface of the insulating region 761. The insulating region 761 has a lower end connected to the insulating region 755 or the insulating region 758. The insulating region 761 contains a material, such as silicon oxynitride, carbon-containing silicon oxide, and silicon nitride, having high resistance against diluted hydrofluoric acid compared with silicon oxide. The insulating region 762 has a lower end connected to the insulating region 754 or the insulating region 757. The insulating region 762 contains silicon oxide.

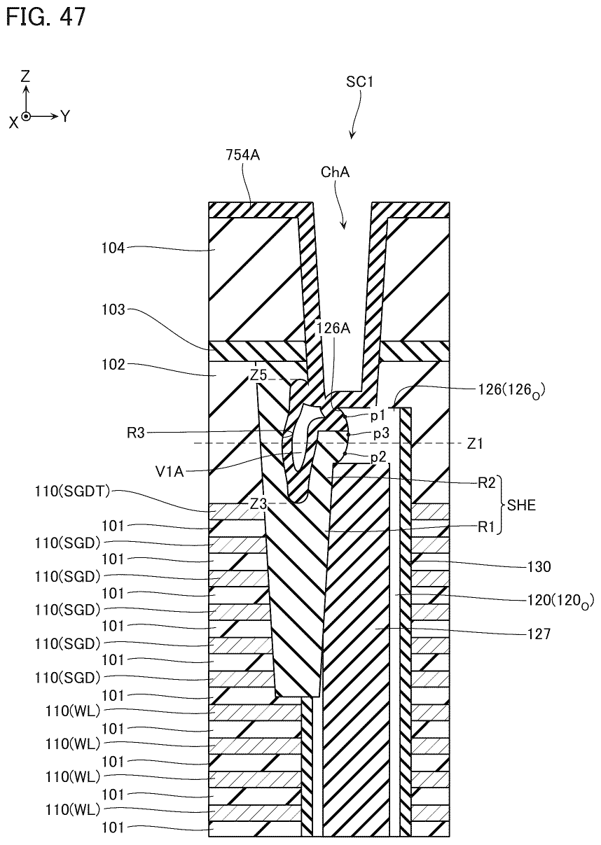

Next, with reference to FIG. 47 to FIG. 50, a method for manufacturing the semiconductor memory device according to the seventh embodiment is described. FIG. 47 to FIG. 50 are schematic cross-sectional views for describing the manufacturing method. FIG. 47 to FIG. 50 illustrate the cross-sectional surface corresponding to FIG. 45.

The semiconductor memory device according to the seventh embodiment is basically manufactured similarly to the semiconductor memory device according to the first embodiment.

However, in the manufacture of the semiconductor memory device according to the seventh embodiment, in the process described with reference to FIG. 28 and FIG. 29, as illustrated in FIG. 47, an insulating member 754A is formed inside the contact hole ChA and cavities V1A, V2A. This process is performed by the method, such as CVD.

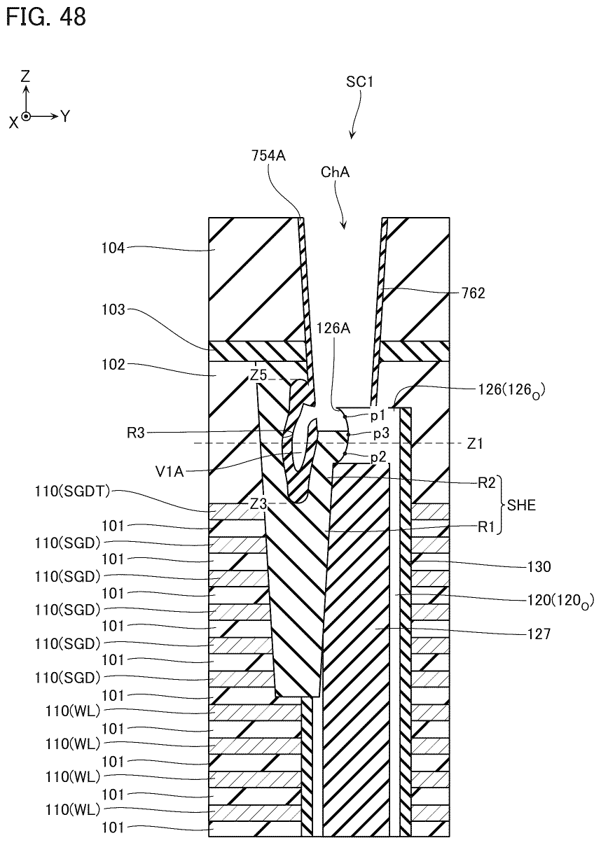

Next, as illustrated in FIG. 48, a part of the insulating member 754A is removed to expose the semiconductor member 126 to the inside of the contact hole ChA. In this process, the insulating member 754A is partially removed by the method, such as RIE.

In the example of FIG. 48, a portion formed on the upper surface of the insulating layer 104 of the insulating member 754A is removed. The portion provided on the inner peripheral surface of the contact hole ChA of the insulating member 754A remains, and is provided as the insulating region 762 of the insulating film 760. Any of the cavities V1A, V2A, the lower region of the contact hole ChA, and the upper region of the contact hole ChA is not filled with the insulating member 754A.

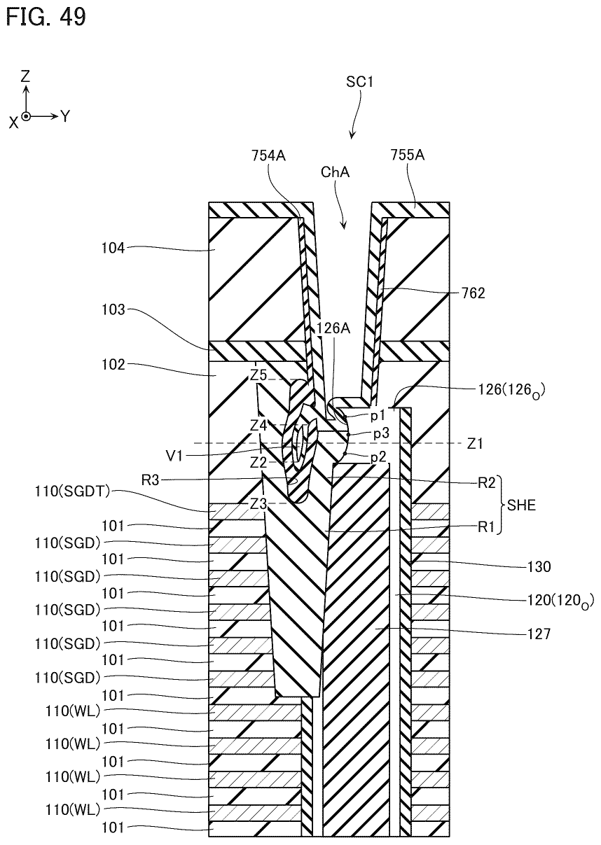

Next, as illustrated in FIG. 49, an insulating member 755A is formed inside the contact hole ChA and the cavities V1A, V2A. This process is performed by the method, such as CVD. In this process, approximately the whole regions of the cavities V1A, V2A (regions excluding the cavities V1, V2) are filled with the insulating member 755A. On the other hand, the upper region of the contact hole ChA is not filled with the insulating member 755A.

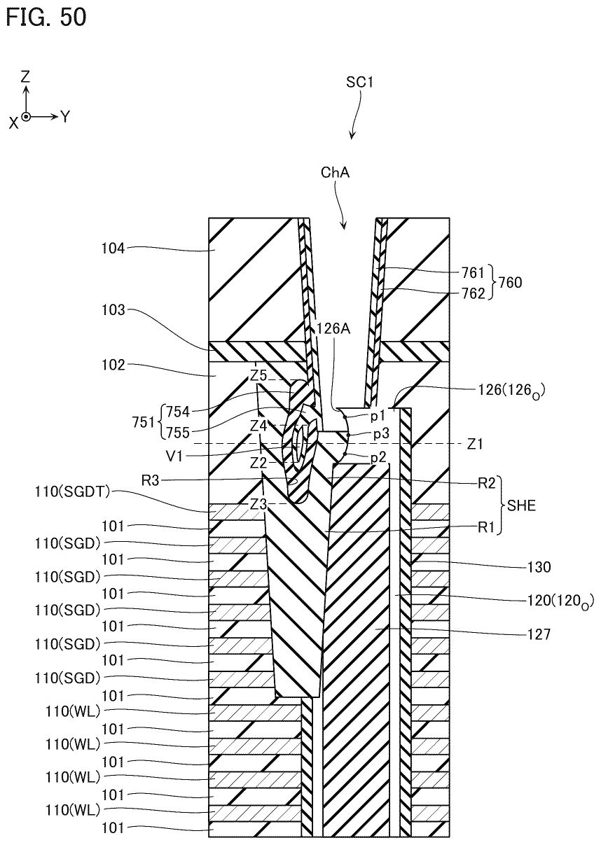

Next, for example, as illustrated in FIG. 50, a part of the insulating member 755A is removed to expose the semiconductor member 126 to the inside of the contact hole ChA. In this process, the insulating member 755A is partially removed by the method, such as RIE. After the insulating member 755A is partially removed, with the use of diluted hydrofluoric acid (DHF) or the like, the residue generated in partially removing the insulating member 754A and the insulating member 755A is removed and the surface of the semiconductor member 126 is cleaned.

In the example of FIG. 50, a portion formed on the upper surface of the insulating layer 104 of the insulating member 755A is removed. The portion provided in the lower region of the contact hole ChA of the insulating member 755A is removed, and the insulating member SHE is exposed from the bottom surface of the contact hole ChA. On the other hand, the portion provided on the inner peripheral surface of the contact hole ChA of the insulating member 755A remains, and is provided as the insulating region 761 of the insulating film 760.

In this embodiment, portions provided at the cavity V1A of the insulating members 754A, 755A are provided as the insulating regions 754, 755 of the insulating member 751. Portions provided at the cavity V2A of the insulating members 754A, 755A are provided as the insulating regions 757, 758 of the insulating member 752 (FIG. 46).

The semiconductor memory device according to the seventh embodiment can provide the effect similar to that of the semiconductor memory device according to the first embodiment as well.

In the semiconductor memory device according to the seventh embodiment, the insulating members 751, 752 include the insulating regions 754, 757 containing silicon oxide, respectively. Accordingly, the occurrence of the short circuit between the contact electrodes Ch can be appropriately reduced. The withstand voltages of the contact electrode Ch and the drain-side select gate line SGDT can be appropriately ensured.

In the semiconductor memory device according to the seventh embodiment, the insulating members 751, 752 include the insulating regions 755, 758 containing the material having high resistance against diluted hydrofluoric acid compared with silicon oxide, respectively. Accordingly, in the process described with reference to FIG. 50, excessive removal of the insulating member 754A can be appropriately reduced.

The insulating members 751, 752 according to the seventh embodiment may include the insulating portions 154, 156 similarly to the insulating members 151, 152 (FIG. 6, FIG. 7, and FIG. 8) according to the first embodiment. The semiconductor memory device according to the seventh embodiment does not need to include a part of or the whole of the insulating film 760. The semiconductor memory device according to the seventh embodiment may include the conductive members ChB (FIG. 38, FIG. 39) instead of the cavities V1, V2 similarly to the semiconductor memory device according to the fourth embodiment. The insulating members 751, 752 according to the seventh embodiment do not need to be internally provided with the cavities V1, V2 similarly to the insulating members 551, 552 (FIG. 42, FIG. 43) according to the fifth embodiment.

### Other Embodiments

The semiconductor memory devices according to the first embodiment to the seventh embodiment are described above. However, these configurations are merely examples, and the specific configuration can be adjusted as appropriate.

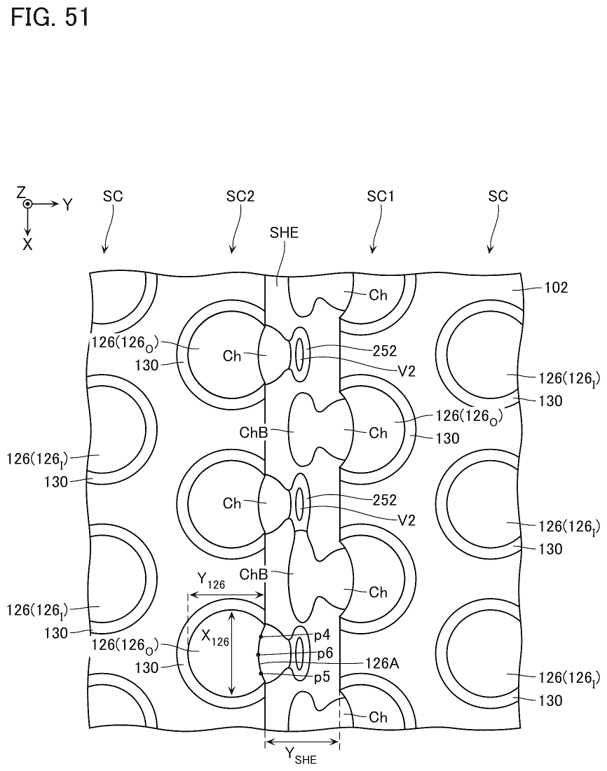

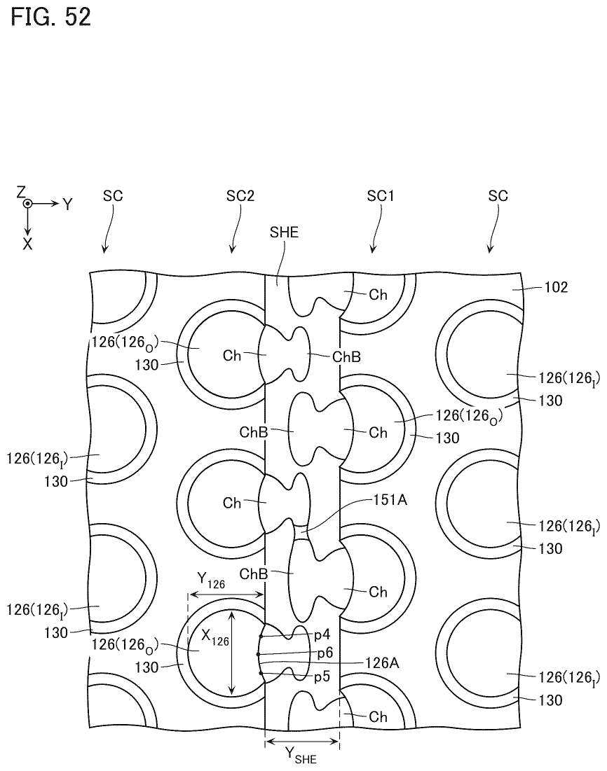

FIG. 51 and FIG. 52 are schematic XY cross-sectional views partially illustrating configurations of semiconductor memory devices according to other embodiments.

For example, in the process described with reference to FIG. 28 and FIG. 29, the cavities V1, V2 may be formed in one of the cavities V1A, V2A, and a cavity does not need to be formed in the other of the cavities V1A, V2A. In the process described with reference to FIG. 24 to FIG. 27, one of the cavities V1A, V2A may be communicated with the contact hole ChA, and the other of the cavities V1A, V2A does not need to be communicated with the contact hole ChA.

For example, in the process described with reference to FIG. 30, the insulating member 151A is partially removed to expose the semiconductor member 126 to the inside of the contact hole ChA, and then the residue is removed using diluted hydrofluoric acid or the like. At this time, a part of the insulating member 151A is further removed. However, as described above, when at least a part of the path between the two contact holes ChA communicated via the cavities V1A, V2A is closed by the insulating member 151A, the occurrence of the short circuit between the contact electrodes Ch can be reduced in at least a part of the cavities V1A, V2A even when a metal or the like constituting the contact electrode Ch enters without passing through the insulating member 151A.

For example, FIG. 51 illustrates an example in which with the process using diluted hydrofluoric acid or the like, the insulating member 151A inside the cavity V1A is removed, and the insulating member 151A inside the cavity V2A remains to be provided as the insulating member 252. In the example of the drawing, while the conductive member ChB is formed in the cavity V1A, at least a part of the cavity V1A may remain as the cavity V1A without the conductive member provided. The inside of the cavity V2A may be completely filled with the insulating member 151A, and the cavity V2 does not need to be provided inside the insulating member 252.

For example, FIG. 52 illustrates an example in which with the process using diluted hydrofluoric acid or the like, while the insulating member 151A is removed in both of the cavity V1A and the cavity V2A excluding the connecting portion between the cavities V1A, V2A, the insulating member 151A remains at the connecting portion between the cavities V1A, V2A. In the example of the drawing, while the conductive member ChB is formed in the cavities V1A and the cavities V2A, at least a part of the cavities V1A, V2A may remain as the cavities V1A, V2A without the conductive member provided.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of conductive layers stacked in a stacking direction;
a first semiconductor column extending in the stacking direction and opposed to the plurality of conductive layers;
a first gate insulating film disposed between the plurality of conductive layers and the first semiconductor column and including a first electric charge accumulating film;
a first semiconductor member connected to one end in the stacking direction of the first semiconductor column;
a first contact electrode extending in the stacking direction and connected to the first semiconductor member;
a first insulating member disposed at a position overlapping with a part of the first semiconductor column and a part of the first gate insulating film when viewed in the stacking direction, the first insulating member separating a part of the conductive layers arranged at a first contact electrode side in the stacking direction among the plurality of conductive layers in a first direction intersecting with the stacking direction; and
a second insulating member disposed at least at a first position in the stacking direction corresponding to the first semiconductor member inside the first insulating member, wherein
the first contact electrode includes:
a first conductive region provided at an opposite side of the first semiconductor column in the stacking direction with respect to a surface of the first semiconductor member at the first contact electrode side in the stacking direction; and
a second conductive region provided at a first semiconductor column side in the stacking direction with respect to the surface of the first semiconductor member between the first semiconductor member and the second insulating member, the second conductive region being in contact with the second insulating member.

2. The semiconductor memory device according to claim 1, wherein
the second insulating member has an etching rate different from an etching rate of the first insulating member.

3. The semiconductor memory device according to claim 1, wherein
the first semiconductor member has a surface at a second insulating member side in the first direction provided with a recessed portion recessed to a first semiconductor member side in the first direction,
the second insulating member is further disposed at a second position at the first semiconductor column side in the stacking direction with respect to the first position,
a length in the first direction of the second insulating member at the second position is smaller than a length in the first direction of the second insulating member at the first position, and
the second insulating member is formed to fill an inside of the first insulating member at least at the second position of the first position and the second position.

4. The semiconductor memory device according to claim 3, wherein
the second insulating member is internally provided with a cavity at the first position, and
the cavity is spaced from the first contact electrode via a part of the second insulating member.

5. The semiconductor memory device according to claim 3, wherein
the second insulating member is internally provided with a conductive member at the first position, and
the conductive member is connected to the first contact electrode.

6. The semiconductor memory device according to claim 3, wherein
the recessed portion has:
a first point and a second point at positions mutually different in the stacking direction; and
a third point provided at a position in the stacking direction between the position of the first point in the stacking direction and the position of the second point in the stacking direction, and
the third point is provided at an opposite side of the second insulating member in the first direction with respect to the first point and the second point.

7. The semiconductor memory device according to claim 3, wherein
the second position is provided at the first contact electrode side in the stacking direction with respect to the plurality of conductive layers.

8. The semiconductor memory device according to claim 1, further comprising:
an insulating film disposed on an outer peripheral surface of the first contact electrode, wherein
the insulating film is connected to the second insulating member.

9. The semiconductor memory device according to claim 1, wherein
the second insulating member contains silicon (Si) and oxygen (O), nitrogen (N) or carbon (C).

10. The semiconductor memory device according to claim 1, wherein
the second insulating member includes:
a first insulating region; and
a second insulating region provided inside the first insulating region,
the second insulating region contains nitrogen (N) or carbon (C), and
the first insulating region does not contain nitrogen (N) or carbon (C).

11. The semiconductor memory device according to claim 1, wherein
the second insulating member is further disposed at:
a second position at the first semiconductor column side in the stacking direction with respect to the first position; and
a third position at the first contact electrode side in the stacking direction with respect to the first position,
a length in the first direction of the second insulating member at the second position is smaller than a length in the first direction of the second insulating member at the first position, and
a length in the first direction of the second insulating member at the third position is smaller than the length in the first direction of the second insulating member at the first position.

12. The semiconductor memory device according to claim 1, wherein
a length in the first direction of the first semiconductor member is smaller than a length in a second direction intersecting with the stacking direction and the first direction of the first semiconductor member.

13. The semiconductor memory device according to claim 1, further comprising:
a second semiconductor column extending in the stacking direction and opposed to the plurality of conductive layers, the second semiconductor column being different from the first semiconductor column in a position in the first direction and a position in a second direction intersecting with the stacking direction and the first direction;
a second gate insulating film disposed between the plurality of conductive layers and the second semiconductor column and including a second electric charge accumulating film;
a second semiconductor member connected to one end in the stacking direction of the second semiconductor column; and
a second contact electrode extending in the stacking direction and connected to the second semiconductor member, the second contact electrode including a third conductive region and a fourth conductive region, the third conductive region being provided at an opposite side of the second semiconductor column in the stacking direction with respect to a surface of the second semiconductor member at a second contact electrode side in the stacking direction, the fourth conductive region being provided at a second semiconductor column side in the stacking direction with respect to the surface of the second semiconductor member between the second semiconductor member and the second insulating member, the fourth conductive region being in contact with the second insulating member, wherein
the second insulating member is disposed to close at least a part of a path formed to extend in the second direction inside the first insulating member in the stacking direction between the second conductive region of the first contact electrode and the fourth conductive region of the second contact electrode.

14. The semiconductor memory device according to claim 1, wherein
an end portion at the first semiconductor column side in the stacking direction of the second conductive region is covered with the first insulating member or the second insulating member.

15. A semiconductor memory device comprising:
a plurality of conductive layers stacked in a stacking direction;
a semiconductor column extending in the stacking direction and opposed to the plurality of conductive layers;
a gate insulating film disposed between the plurality of conductive layers and the semiconductor column and including an electric charge accumulating film;
a semiconductor member connected to one end in the stacking direction of the semiconductor column;
a contact electrode extending in the stacking direction and connected to the semiconductor member;
a first insulating member disposed at a position overlapping with a part of the semiconductor column and a part of the gate insulating film when viewed in the stacking direction, the first insulating member separating a part of the conductive layers arranged at a contact electrode side in the stacking direction among the plurality of conductive layers in a first direction intersecting with the stacking direction; and
a second insulating member disposed at least at a first position in the stacking direction corresponding to the semiconductor member inside the first insulating member, the second insulating member having one end portion and the other end portion in the stacking direction and a surface at an opposite side of the semiconductor member in the first direction spaced from one end portion and the other end portion in the stacking direction of the first insulating member and formed along the first insulating member.

16. The semiconductor memory device according to claim 15, wherein
the second insulating member has an etching rate different from an etching rate of the first insulating member.

17. The semiconductor memory device according to claim 15, wherein
the semiconductor member has a surface at a second insulating member side in the first direction provided with a recessed portion recessed to a semiconductor member side in the first direction,
the second insulating member is further disposed at a second position at a semiconductor column side in the stacking direction with respect to the first position,
a length in the first direction of the second insulating member at the second position is smaller than a length in the first direction of the second insulating member at the first position, and
the second insulating member is formed to fill an inside of the first insulating member at least at the second position of the first position and the second position.

18. A semiconductor memory device comprising:
a plurality of conductive layers stacked in a stacking direction;
a first semiconductor column extending in the stacking direction and opposed to the plurality of conductive layers;
a second semiconductor column extending in the stacking direction and opposed to the plurality of conductive layers, the second semiconductor column being different from the first semiconductor column in a position in a first direction intersecting with the stacking direction and a position in a second direction intersecting with the stacking direction and the first direction;
a first gate insulating film disposed between the plurality of conductive layers and the first semiconductor column and including a first electric charge accumulating film;
a second gate insulating film disposed between the plurality of conductive layers and the second semiconductor column and including a second electric charge accumulating film;
a first semiconductor member connected to one end in the stacking direction of the first semiconductor column;
a second semiconductor member connected to one end in the stacking direction of the second semiconductor column;
a first contact electrode extending in the stacking direction and connected to the first semiconductor member;
a second contact electrode extending in the stacking direction and connected to the second semiconductor member;
a first insulating member disposed between the first semiconductor column and the second semiconductor column so as to overlap with a part of the first semiconductor column and a part of the second semiconductor column when viewed in the stacking direction, the first insulating member extending in the second direction and separating a part of the conductive layers arranged at a first contact electrode side in the stacking direction among the plurality of conductive layers in the first direction; and
a second insulating member disposed at least at a first position in the stacking direction corresponding to the first semiconductor member and the second semiconductor member inside the first insulating member, wherein
the second insulating member is disposed to close at least a part of a path formed to extend in the second direction inside the first insulating member in the stacking direction between a first region opposed to a side surface of the first contact electrode at a first insulating member side in the first direction and a second region opposed to a side surface of the second contact electrode at the first insulating member side in the first direction.

19. The semiconductor memory device according to claim 18, wherein
the second insulating member has an etching rate different from an etching rate of the first insulating member.

20. The semiconductor memory device according to claim 18, wherein
the first region and the second region are internally provided with a cavity or a conductive member,
the cavity or the conductive member inside the first region is spaced from the cavity or the conductive member inside the second region via the second insulating member.
